(19) United States
(12) Patent Application Publication
(10) Pub. No.: US 2025/0216842 A1
(43) Pub. Date: Jul. 3, 2025

(54) COMPUTER IMPLEMENTED METHOD FOR DEFECT DETECTION IN AN IMAGING DATASET OF A WAFER, CORRESPONDING COMPUTER-READABLE MEDIUM, COMPUTER PROGRAM PRODUCT AND SYSTEMS MAKING USE OF SUCH METHODS

(71) Applicant: Carl Zeiss SMT GmbH, Oberkochen (DE)

(72) Inventors: Abhilash SRIKANTHA, Neu-Ulm (DE); Anna ALPEROVICH, Neu-Ulm (DE); Bjoern BARZ, Jena (DE); Niklas MEVENKAMP, Jena (DE); Jens Timo NEUMANN, Aalen (DE); Eugen FOCA, Ellwangen (DE); Johannes PERSCH, Etgert (DE)

(21) Appl. No.: 19/085,234

(22) Filed: Mar. 20, 2025

Related U.S. Application Data
(63) Continuation of application No. PCT/EP2023/074370, filed on Sep. 6, 2023.

(30) Foreign Application Priority Data
Sep. 28, 2022 (DE) 10 2022 125 015.6

(51) Int. Cl. G05B 19/418

(52) U.S. Cl. CPC G05B 19/41875; G05B 2219/32368; G05B 2219/45031

(57) ABSTRACT

A computer implemented method for defect detection comprises obtaining an imaging dataset of a wafer, and verifying a defect criterion in a subset of the imaging dataset of the wafer. The defect criterion comprises an observation representation of the subset of the imaging dataset with respect to a number of characteristic elements derived from reference images of semiconductor structures. The observation representation and the characteristic elements define a reconstruction of minimal reconstruction error, and a tolerance statistic on defect-free representations of subsets of defect-free observed imaging datasets. Each of the defect-free representations and the characteristic elements define a reconstruction of minimal reconstruction error of a subset of the defect-free imaging datasets. The computer implemented method further comprises generating defect information.

### CROSS-REFERENCE TO RELATED APPLICATIONS

The present application is a continuation of, and claims benefit under 35 USC 120 to, international application No. PCT/EP2023/074370, filed Sep. 6, 2023, which claims benefit under 35 USC 119 of German Application No. 10 2022 125 015.6, filed Sep. 28, 2022. The entire disclosure of each of these applications is incorporated by reference herein.

### FIELD

The disclosure relates to systems and methods for quality control and quality assurance for wafers comprising semiconductor structures, more specifically to a computer implemented method, a computer-readable medium, a computer program product and corresponding systems for defect detection in an imaging dataset of a wafer. The method, computer-readable medium, computer program product and systems involve a computer implemented method for defect detection comprising obtaining an imaging dataset of a wafer including semiconductor structures and the verification of a defect criterion. The method, computer program product and systems for semiconductor inspection can be utilized for quantitative metrology, defect detection, process monitoring, or defect review of integrated circuits within semiconductor wafers.

### Background

Semiconductor manufacturing generally involves precise manipulation, e.g., etching, of materials such as silicon or oxide at very fine scales in the range of nanometers (nm). Therefore, a quality management process comprising quality assurance and quality control is relevant to ensuring high quality standards of the manufactured wafers. Quality assurance refers to a set of activities for ensuring high-quality products by preventing any defects that may occur in the development process. Quality control refers to a system of inspecting the final quality of the product. Quality control is part of the quality assurance process.

A wafer made of a thin slice of silicon typically serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patters are subject to several influences. For example, during the manufacturing of 3D-memory devices, the processes currently include etching and deposition. Other process steps such as the lithography exposure or implantation also can have an impact on the properties of the elements of the integrated circuits. Therefore, fabricated semiconductor structures can suffer from rare and different imperfections. Devices for quantitative metrology, defect-detection or defect review look for these imperfections. These devices are not only desirable during wafer fabrication. As this process is relatively complicated and highly non-linear, optimization of production process parameters can be difficult. As a remedy, an iteration scheme called process window qualification (PWQ) can be applied. In each iteration a test wafer is manufactured based on the currently best process parameters, with different dies of the wafer being exposed to different manufacturing conditions. By detecting and analyzing the defects in the different dies based on a quality assurance process, the best manufacturing process parameters can be selected. In this way, production process parameters can be tweaked towards optimality. Afterwards, a highly accurate quality control process and device for the metrology semiconductor structures in wafers is involved.

The recognized defects are, thus, used for root cause analysis. They can serve as feedback to improve the process parameters of the manufacturing process during quality assurance, e.g., exposure time, focus variation, etc., or they can serve for ensuring the quality of manufactured wafers during quality control. For example, bridge defects can indicate insufficient etching, line breaks can indicate excessive etching, consistently occurring defects can indicate a defective mask and missing structures hint at non-ideal material deposition etc. Other defects can arise from defects or contamination from various sources, for example degeneration of lithography masks or particle contamination.

Fabricated semiconductor structures are typically based on prior knowledge. The semiconductor structures are manufactured from a sequence of layers being parallel to a substrate. For example, in a logic type sample, metal lines are running parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average. Furthermore, a semiconductor wafer has a diameter of 300 mm and include a plurality of several sites, so called dies, each comprising at least one integrated circuit pattern such as for example for a memory chip or for a processor chip. During fabrication, semiconductor wafers run through about 1000 process steps, and within the semiconductor wafer, about 100 and more parallel layers are formed, comprising the transistor layers, the layers of the middle of the line, and the interconnect layers and, in memory devices, a plurality of 3D arrays of memory cells.

The aspect ratio and the number of layers of integrated circuits constantly increases and the structures are growing into the third (vertical) dimension. The current height of the memory stacks is exceeding a dozen of microns. In contrast, the features size is becoming smaller. The minimum feature size or critical dimension is below 10 nm, for example 7 nm or 5 nm, and will approach feature sizes below 3 nm in the near future. While the complexity and dimensions of the semiconductor structures are growing into the third dimension, the lateral dimensions of integrated semiconductor structures are becoming smaller. Therefore, measuring the shape, dimensions and orientation of the features and patterns in 3D and their overlay with high precision can become challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter generally has a limited dimension, which depends on the charged particle beam operation conditions and lens. The beam resolution is generally limited by approximately half of the beam diameter. The lateral resolution can be below 2 nm, for example even below 1 nm.

A task of semiconductor inspection is to determine a set of specific parameters of semiconductor objects such as high aspect ratio (HAR)-structures inside the inspection volume. Such parameters are for example a dimension, area, a shape, or other measurement parameters. Typically, the measurement task of the prior art involves several computational steps like object detection, feature extraction, and any kind of a metrology operation, for example a computation of a distance, a radius or an area from the extracted features. Of these many steps, each involves a high computational effort.

Generally, semiconductors comprise many repetitive three-dimensional structures. During the manufacturing process or a process development, some selected physical or geometrical parameters of a representative plurality of the three-dimensional structures are measured with high accuracy and high throughput. For monitoring the manufacturing, an inspection volume is defined, comprising the representative plurality of the three-dimensional structures. This inspection volume is then analyzed for example by a slice and image approach, leading to a 3D volume image of the inspection volume with high resolution obtained by slicing and imaging a plurality of cross-section surfaces within the inspection volume.

The plurality of repetitive three-dimensional structures inside an inspection volume can exceed several 100 or even several thousand individual structures. Thereby, a huge number of cross section images is generated, for example at least 100 three-dimensional structures are investigated by 100 cross section image slices, thus the number of measurements to be performed may easily reach 10000 or more.

Current technologies such as multibeam scanning electron microscopy (multibeam SEM) can be used for imaging large regions of a wafer surface with high resolution in a short period of time. To this end, multibeam SEM uses multiple single beams in parallel, each beam covering a separate portion of a surface, with pixel sizes down to 2 nm. The resulting datasets are huge and cannot be analyzed manually.

In order to analyze large amounts of data using large amounts of measurements to be taken, machine learning methods can be used. These are suitable for analyzing large amounts of data while limiting interaction with a user to a minimum.

Machine learning is a field of artificial intelligence. Machine learning methods generally build a parametric machine learning model based on training data including a large number of samples. After training, the method is able to generalize the knowledge gained from the training data to new previously unencountered samples, thereby making predictions for new data. There are many machine learning methods, e.g., linear regression, k-means, support vector machines, neural networks or deep learning approaches.

Methods for the automatic detection of defects are often based on a die-to-die or die-to-database principle. The die-to-die principle compares portions of a wafer with other portions of the same wafer thereby discovering deviations from the typical or average wafer design. The die-to-database principle compares portions of a wafer with defect-free reference data, e.g., defect-free observed images of wafers or generated images of wafers such as simulated images or CAD-files, thereby discovering deviations from the ideal data. Unexpected patterns in the imaging dataset, i.e., anomalies, are detected due to large differences and are subsequently analyzed to derive classification criteria, e.g., thresholds, area coverage, aspect ratio, etc.

Yet not all anomalies are defects: for instance, anomalies can also include, e.g., imaging artefacts, image acquisition noise, varying imaging conditions, variations of the semiconductor structures within the norm, rare semiconductor structures or variations due to imperfect lithography, varying manufacturing conditions or varying wafer treatment, registration errors, etc. Such anomalies that are not defects but still deviate from the norm for some reason and are, thus, detected by some anomaly detection method, are referred to as nuisances in the following.

Defect detection methods applied to imaging datasets of wafers can, therefore, face the problem of a very high nuisance rate n, which is the inverse of the precision rate p, i.e., n=1−p, since far too many and mostly irrelevant deviations on wafer surfaces are discovered. Consequently, defect detection algorithms often involve extensive post-processing to discriminate between nuisances and real defects.

Known approaches often use die-to-database approaches by registering an observed imaging dataset of a wafer to a reference imaging dataset and thresholding the difference. Alternatively, die-to-die approaches are common, which are based on machine learning models such as autoencoders. These models learn to reconstruct only defect-free images, so defects can be detected based on the difference between the observed image and its reconstruction. However, all of these approaches are prone to detect nuisances along with real defects, so these approaches are of limited usability for defect detection in wafers.

For example, U.S. Pat. No. 6,678,404 B1 discloses a defect detection approach for computer vision applications. Defects are detected based on thresholding the difference between a reference image and an input image. To improve defect detection results, a mean reference image and a variance reference image are computed from a number of reference images. The mean reference image and the variance reference image contain at each pixel the mean or respectively the variance of all reference images at the pixel. The deviations of the input image from the reference image at a pixel is then weighted based on the mean and variance at the pixel of the mean and variance image. Yet, this approach may not be suitable for distinguishing real defects from nuisances.

US 2022/0044391 A1 describes a defect detection approach for wafer images that uses a generative adversarial neural network to estimate the design underlying the wafer image. Defects are then detected by comparing the estimated design to the true design underlying the wafer image. To improve the estimated design, several estimated designs can be averaged. However, this approach may not be suitable for distinguishing defects from nuisances.

WO2021181749A1 discloses a defect detection approach, wherein a reference image is learned from multiple object images and the error between an input image and a reference image is reduced by considering the statistics of the input image pixels. Again, this approach may not be suitable for distinguishing real defects from nuisances.

U.S. Pat. No. 10,504,692 B2 discloses a defect detection approach, wherein a defect is detected in a region of an input image by computing a sparse representation of the region and calculating the number of atoms used for its representation. However, counting the number of atoms representing the region may not be suitable for distinguishing nuisances from real defects.

### SUMMARY

The disclosure seeks to provide a wafer inspection method for the measurement of semiconductor structures in inspection volumes with high accuracy. The disclosure also seeks to improve the accuracy of defect detection methods, such as to distinguish real defects from nuisances. Further, the disclosure seeks to adapt defect detection methods to imaging datasets of wafers, such as for quality control or quality assurance processes. The disclosure also seeks to provide a generalized wafer inspection method for the measurement of semiconductor structures in inspection volumes, which can quickly be adapted to changes of the measurement tasks, the measurement system, or to changes of the semiconductor object of interest. In addition, the disclosure seeks to provide a robust and reliable measurement method of a set of parameters describing semiconductor structures in an inspection volume with high precision and with reduced measurement artefacts.

Embodiments of the disclosure concern computer implemented methods, computer-readable media, computer program products and systems implementing defect detection methods for imaging datasets of wafers.

A first embodiment involves a computer implemented method for defect detection comprising: obtaining an imaging dataset of a wafer comprising semiconductor structures; verifying a defect criterion for defect detection in a subset of the imaging dataset of the wafer, the defect criterion comprising an observation representation of the subset of the imaging dataset with respect to a number of characteristic elements derived from reference images of semiconductor structures, wherein the observation representation and the characteristic elements define a reconstruction of minimal reconstruction error of the subset of the imaging dataset, and a tolerance statistic on defect-free representations of subsets of defect-free observed imaging datasets of wafers, wherein each of the defect-free representations and the characteristic elements define a reconstruction of minimal reconstruction error of the subset of the defect-free imaging dataset; generating defect information for the subset of the imaging dataset based on the defect criterion.

This method can allow for distinguishing between defects and nuisances, thereby increasing the accuracy of the defect detection method, for the following reasons. The characteristic elements are derived from reference images of semiconductor structure, i.e., images without defects, e.g., CAD-files. Therefore, the characteristic elements mainly represent defect-free structures. Based on the characteristic elements an observation representation of a subset of an observed, possibly defective, imaging dataset can be obtained. If the observed imaging dataset contains defects or nuisances, these deviations from the ideal or defect-free semiconductor structures encoded by the characteristic elements cannot be represented yielding a considerable reconstruction error. Yet, if only the reconstruction error was used as indicator of a defect, nuisances and defects would be detected alike. Therefore, a tolerance statistic is learned from defect-free representations of defect-free observed imaging datasets. These datasets contain unavoidable nuisances, e.g., line shortening, line thinning or edge roughness, but no defects. Therefore, the tolerance statistic obtained from defect-free representations of defect-free observed imaging datasets comprises deviations due to nuisance, but no deviations due to real defects. Hence, this tolerance statistic allows to distinguish observation representations of subsets of observed imaging datasets comprising defects from those comprising only nuisance.

Throughout this application, an imaging dataset, a defect-free observed imaging dataset or a reference image can comprise the grey level values of the raw image data themselves or values derived from these grey level values via some operation applied to the imaging dataset, the defect-free observed imaging dataset or the reference image, e.g., gradients, derivatives, feature vectors of one or more dimensions such as filter responses, e.g. smoothing filters, values obtained by some pre-processing method, e.g. edge detection image values, etc. In this way, the methods disclosed herein can be applied to the acquired raw image data or to any kind of pre-processed image data.

Throughout this application a subset of an imaging dataset means a section of the imaging dataset or the whole imaging dataset. An imaging dataset comprises one or more images, for example a volume of images. The imaging datasets can be acquired via a charged particle beam imaging system.

The generated defect information for the subset based on the defect criterion can, for example, comprise an indicator ‘defect’/′no defect′, a defect probability or a defect segmentation.

A statistic is any quantity computed from a number of samples or observations which is considered for a statistical purpose, e.g., mean, variance, moments, probability density functions. Statistical purposes include but are not limited to estimating a population parameter or a population, describing a sample, or evaluating a hypothesis.

The tolerance statistic obtained from defect-free representations of defect-free observed imaging datasets can be used in different ways, e.g., 1) as a direct indicator of a defect based on a comparison of an observation representation of a subset of an imaging dataset with a property of the tolerance statistic. According to an example of the first embodiment of the disclosure, the defect criterion comprises detecting a defect in the subset based on a statistical property of the obtained observation representation with respect to the tolerance statistic. For example, the statistical property can comprise a quantile of the statistic, for example a threshold, a confidence interval or a moment of the statistic, in particular a mean value and/or a variance. Based on the statistical property, an observation representation of a subset of an imaging dataset can directly be labeled as ‘defect’ or ‘not defect’ thereby distinguishing between nuisances and defects.

The tolerance statistic can also be used in a different way, e.g., 2) as prior in an optimization problem for obtaining the observation representation of a subset of an imaging dataset with respect to the number of characteristic elements. After obtaining the observation representation as a solution of the optimization problem, a defect can be detected based on the reconstruction error associated with the obtained observation representation. In an example of the first embodiment of the disclosure, therefore, the observation representation of the subset is obtained by solving an optimization problem comprising the reconstruction error and a prior comprising the tolerance statistic on defect-free representations. The defect criterion can comprise detecting a defect in the subset of the obtained imaging dataset based on the reconstruction error of the solution to the optimization problem. By using the tolerance statistic as a prior in the optimization problem used to compute the observation representation of the subset, the tolerance statistic directly influences the observation representation of the subset by preventing observation representations of low likelihood. This will increase the reconstruction error for defects, but not for nuisances, which have a higher likelihood according to the tolerance statistic. Therefore, defects can be detected based on the reconstruction error of the obtained observation representation.

Throughout this application, the property “defect-free” of a dataset refers to a dataset that is predominantly defect-free, i.e., less than 10% of the dataset, such as less than 5% of the dataset, for example less than 2% of the dataset, for example less than 1% of the dataset contains a defect.

The term “characteristic elements” that are derived from reference images of semiconductor structures can refer to some kind of features, e.g., a set of feature vectors or images, that represent properties of the reference images. Features can, for example, comprise subsets of the reference images or processed subsets of the reference images (e.g., by modifying contrast, brightness, intensity, color, or by applying filters such as edge detectors, shape detectors, etc.). Features can, for example, comprise any kind of subspace or basis derived from the reference images that is defined by a set of feature vectors or images (e.g., by using subspace methods such as principal component analysis or independent component analysis, dictionary methods, clustering methods, wavelet or Fourier bases, etc.,). The term “characteristic elements” can also refer to a set of parameters of a function that maps a subset of an imaging dataset to an observation representation of the subset of the imaging dataset, wherein the set of parameters is derived from reference images, e.g., the term “characteristic elements” can refer to the parameters of a machine learning model, such as a neural network, that are learned from reference images.

In an example of the first embodiment of the disclosure the defect criterion further comprises modifying the defect detection result or an intermediate result of the defect detection method via a trained machine learning model. In this way, the accuracy of the defect detection method can be improved by using a second source of information. The trained machine learning model can be applied to the subset of the imaging dataset of the wafer and/or to a difference of the subset of the imaging dataset of the wafer and an aligned reference image, such as an emulated aligned reference image, and/or to the reconstruction error of the observation representation of the subset of the imaging dataset of the wafer. The trained machine learning model can use a region of interest comprising the subset of the imaging dataset of the wafer and/or a region of interest comprising the difference of the subset of the imaging dataset of the wafer and an aligned reference image, such as an emulated aligned reference image, and/or a region of interest comprising the reconstruction error of the observation representation of the subset of the imaging dataset of the wafer as input. The trained machine learning model can comprise an autoencoder or a segmentation model.

A second embodiment of the disclosure concerns a computer implemented method for obtaining a tolerance statistic on defect-free representations of subsets of defect-free observed imaging datasets of wafers, comprising the following steps: obtaining defect-free observed imaging datasets of wafers comprising semiconductor structures; generating defect-free representations of subsets of defect-free observed imaging datasets of wafers with respect to a number of characteristic elements derived from reference images of semiconductor structures, wherein each of the defect-free representations and the characteristic elements define a reconstruction of minimal reconstruction error of a subset of the defect-free observed imaging datasets, and obtaining a tolerance statistic on the defect-free representations. This method allows to derive a tolerance statistic on properties of defect-free observed imaging datasets, which contain nuisances but no defects. This tolerance statistic then allows to distinguish between observation representations of defective subsets of imaging datasets, which are of low likelihood, and observation representations of subsets of imaging datasets containing only nuisances, which are of higher likelihood.

An example of the second embodiment of the disclosure can further comprise, before generating the defect-free representations, obtaining a number of characteristic elements from reference images of semiconductor structures by solving an optimization problem comprising a minimal reconstruction error of reconstructions of reference images, the reconstructions being defined by reference representations and the characteristic elements.

By obtaining the characteristic elements from reference images, whereas the tolerance statistic is obtained from defect-free observed imaging datasets, the tolerance statistic is able to model the difference between nuisance and defect. The tolerance statistic encompasses deviations from the reference images due to nuisances, since nuisances also occurs in defect-free observed imaging datasets, but the tolerance statistic does not encompass deviations due to defects. In this way, nuisances can be distinguished from defects.

According to an example of the second embodiment of the disclosure, the optimization problem comprises at least one constraint or prior on a characteristic element. In this way, characteristic elements meeting certain desired properties can be computed, or multiple solutions only differing by insignificant properties, can be avoided, or the solution set of the optimization problem can be suitably restricted to simplify optimization. For example, the constraint or prior can involve an Lp-norm of the characteristic element, or the sparsity of the characteristic element, in particular the L0-norm or the L1-norm of the characteristic element.

According to an example of the second embodiment of the disclosure, the optimization problem comprises at least one constraint or prior on a reference representation. In this way, reference representations meeting certain desired properties can be computed, e.g., sparsity or smoothness properties, leading to results of higher accuracy. For example, the constraint or prior can involve an Lp-norm of a reference representation or of the gradient of reference representations of neighboring subsets of reference images, in particular the L2-norm or the L1-norm. The constraint or prior can be a measure of sparsity of the reference representation, for example the L0-norm or the L1-norm or the kurtosis of the reference representation.

A sparse representation is a representation comprising only a few non-zero elements. This increases the accuracy of the method, since a sparse representation of a subset is a composition of few characteristic elements only. This can help prevent defects from being approximately represented by a combination of many different characteristic elements, which might lead to a low reconstruction error not detected as defect. The kurtosis measures the degree of normality of the distribution of the elements of the representation. Therefore, a sparse representation has low kurtosis.

According to an example of the first or second embodiment of the disclosure, the tolerance statistic comprises a probability density function obtained from the defect-free representations of defect-free observed imaging datasets by a density estimation technique. This is beneficial, since the estimated probability density function is a better estimate of the true underlying probability density function than the samples or a relative frequency statistic, e.g., the probability density function can be bias free and continuous. Therefore, the accuracy of the method is improved.

According to an example of the first or second embodiment of the disclosure, the tolerance statistic comprises a joint probability density function f (S,R) or a conditional probability density function f (S|R) obtained by a density estimation technique, wherein S comprises observation representations of subsets of observed imaging datasets and/or defect-free representations of subsets of defect-free observed imaging datasets, and wherein R comprises reference representations of subsets of reference images with respect to a number of characteristic elements. By using a joint or conditional probability density function, rare semiconductor structures or rare nuisances can be modeled by the probability density function without having probabilities close to 0, thus improving the accuracy of the method.

The representations S can be based on the same number of characteristic elements as the representations in R or on an additional number of characteristic elements, e.g., derived from observation representations of subsets of imaging datasets and/or defect-free representations of subsets of defect-free observed imaging datasets. According to an example of the first or second embodiment of the disclosure, a number of additional characteristic elements can be derived from observed imaging datasets, and the observation representations and/or defect-free representations S can be based on the additional characteristic elements, while the reference representations R of reference images can be based on the characteristic elements derived from reference images.

The probability density function of the tolerance statistic can be obtained by a parametric density estimation technique, for example the probability density function of a Gaussian or a Gaussian mixture model. This can mean that only a few parameters of a predefined probability density function are estimated from the defect-free representations, so a small number of defect-free representations can still yield satisfactory results. In addition, some probability density functions are especially simple to handle, e.g., the Gaussian probability density function.

Alternatively, the probability density function of the tolerance statistic can be obtained by a non-parametric density estimation technique, such as a Parzen density estimator. These methods can provide a higher accuracy, since for infinitely many samples the estimated probability density function converges to the true underlying probability density function.

In an example, the tolerance statistic can also comprise a machine learning model trained on the defect-free representations, such as a one-class SVM or a support vector data description (SVDD). The one-class SVM, for example, is trained on defect-free observed imaging datasets and is able to identify outliers, that is defects, based on a distance measure.

The tolerance statistic can comprise only a subset of the dimensions of the defect-free representations. This can save computation time and limit the tolerance statistic to relevant dimensions. The tolerance statistic can also comprise a separate tolerance statistic for each dimension of the subset of dimensions of the defect-free representations. This can simplify the computation of the tolerance statistic or the application of the tolerance statistic to defect detection, since one-dimensional statistics are simpler to handle than multivariate statistics, e.g., for the computation of quantiles or confidence intervals.

According to an example of the first or second embodiment of the disclosure, the observation representation of the subset of the imaging dataset comprises a registration vector indicating the offset between the subset of the imaging dataset and a characteristic element in the form of a corresponding subset of a reference image, such that the corresponding subset of the reference image is registered with the subset of the imaging dataset via the registration vector, and wherein the defect-free representations of the subsets of the defect-free observed imaging datasets comprise registration vectors indicating the offset between the subsets of the defect-free observed imaging datasets and characteristic elements in the form of corresponding subsets of reference images, such that the corresponding subsets of the reference images are registered with the subsets of the defect-free observed imaging datasets via the registration vectors. In this way, a registration vector is computed between a characteristic element in the form of a subset of a reference image and the corresponding subset of the imaging dataset of the wafer, or vice versa, thereby minimizing the reconstruction error.

The reconstruction error of a subset of an imaging dataset can comprise the warping error between the subset of the imaging dataset and the corresponding subset of the reference image, or vice versa, and the reconstruction error of a defect-free representation of a subset of a defect-free observed imaging dataset can comprise the warping error between the subset of the defect-free observed imaging dataset and the corresponding subset of the reference image, or vice versa. The warping error between a first and a second image comprises the deviation of the first image from the registered second image, i.e., the second image warped according to the associated registration vectors. For example, the warping error can be measured by the deviation of the subset of the reference image warped according to the registration vector and the subset of the imaging dataset of the wafer, or vice versa. The deviation can, for example, be measured by the squared sum of the difference of the grey level values. For a subset of an imaging dataset comprising a number of pixels a registration vector field can be computed by optimizing a known registration optimization problem, e.g., an optimization problem comprising the warping error and a norm of the gradient of neighboring registration vectors. Based on the tolerance statistic on registration vectors, a likelihood for a defect can be assigned to each registration vector of the registration vector field. Using registration vectors as observation representations of subsets of imaging datasets and/or as defect-free representations of subsets of defect-free observed imaging datasets can help improve the accuracy of the defect detection method.

According to an example of the first or second embodiment of the disclosure, the number of characteristic elements can comprise a machine learning model, such as a neural network in the form of an autoencoder, trained on reference images of semiconductor structures, and the observation representation of the subset of the imaging dataset can comprise the output of the machine learning model when applied to the subset of the imaging dataset, and the defect-free representations of the subsets of the defect-free observed imaging datasets can comprise the output of the machine learning model when applied to the subsets of the defect-free observed imaging datasets. Constraints can, for example, be imposed on the parameters of the machine learning model, e.g., on the size or number of layers of a neural network. The machine learning model can, for example, learn to reduce the dimensionality of the input data. Using the output of a machine learning model as observation representations of subsets of imaging datasets and/or as defect-free representations of subsets of defect-free observed imaging datasets can help improve the accuracy of the defect detection method.

According to an example of the first or second embodiment of the disclosure, the observation representation of the subset of an imaging dataset comprises coefficients of a decomposition of the subset of the imaging dataset with respect to the number of characteristic elements, and the defect-free representations of the subsets of the defect-free observed imaging datasets comprise coefficients of decompositions of the subsets of the defect-free observed imaging datasets with respect to the number of characteristic elements. In this way, characteristic elements can be learned from reference images meeting any desired property suitable for the defect detection task. For example, a small number of orthogonal characteristic elements yields low dimensional representations as in subspace learning techniques, thereby reducing computation time and effort. In contrast, a large number of characteristic elements representing typical structures of the input data as in sparse coding techniques leads to highly accurate defect detection methods.

Instead of using the subset of an imaging dataset, the subset of a defect-free imaging dataset or the subset of a reference image, the methods disclosed herein can also be applied to difference images, e.g., to the difference image of a subset of an imaging dataset and an aligned corresponding subset of a reference image, to a difference image of a subset of a defect-free imaging dataset and an aligned corresponding subset of a reference image, to a difference image of a subset of an imaging dataset and an aligned subset of a defect-free observed imaging dataset, etc.

Instead of deriving the characteristic elements and the tolerance statistic from reference images, they can also be derived from difference images of subsets of defect-free observed imaging datasets and aligned subsets of reference images, and the observation representation and defect-free representation of a subset can comprise coefficients of a decomposition of a difference image of the subset and an aligned reference image with respect to the number of characteristic elements. In this way, the observation representation and the defect-free representation only encodes the differences between the images instead of the information contained in the images themselves as well, which reduces the complexity of the characteristic elements and the observation representations and the defect-free representations and, thus, increases the accuracy of the defect detection methods.

The decomposition of a subset can be non-linear or linear. The characteristic elements can comprise elements of a basis, for example of a wavelet basis, of a Fourier basis, or of a principal component basis obtained by principal component analysis. The characteristic elements can also comprise elements of an overcomplete frame. An overcomplete frame refers to a set of vectors, which can be linearly dependent, and based on which each subset of the reference images can be approximated arbitrarily well in norm by a finite combination of vectors. The characteristic elements can comprise elements of a dictionary obtained via dictionary learning or a number of independent components obtained via independent component analysis. The characteristic elements can also comprise a number of image-patches obtained by an unsupervised clustering method. A specific selection of characteristic elements allows to adapt the defect detection method to a number of different use-cases making it versatile and, thereby, improving the accuracy of the defect detection method.

In an example of the first or second embodiment of the disclosure, the reference images of semiconductor structures comprise subsets of defect-free observed imaging datasets of semiconductor structures or subsets of defect-free generated images of semiconductor structures, in particular synthetic images of defect-free semiconductor structures. Defect-free generated images of semiconductor structures can comprise a number of polygons representing semiconductor structures, or images generated from a defect-free CAD model of a wafer, or defect-free images generated by a neural network. The reference images can also comprise defect-free generated images of semiconductor structures and defect-free observed images of the semiconductor structures. The reference images can be aligned for an improved accuracy, e.g., a number of reference images can be aligned with respect to one another. In this way, characteristic elements, e.g., typical structures of defect-free images, can be learned from large numbers of aligned reference images. Reference images can also be aligned to observed imaging datasets of wafers. In this way, structures of observed imaging datasets and reference images can be compared, e.g., observed structures to corresponding structures of reference images, e.g., via a difference image. In this way, defects can be detected.

The generated images of semiconductor structures can be emulated to have an appearance similar to an observed imaging dataset of the wafer by simulating the image acquisition process and the lithography process for an improved accuracy.

To emulate an image, a physics-inspired forward simulation of the imaging process for the given charged particle beam imaging system can be applied to the image. The simulation typically comprises a scaling of the image according to the pixel raster of the selected scanning method. A spatially resolved image contrast is determined by the material contrast of the materials present in the image. After scaling and application of the material contrast values, a convolution of the image with a convolution kernel according to the point spread function of the imaging system is performed. The point spread function can be determined according to an expected interaction volume generated by the primary charged particle imaging beam at a cross section through the wafer. The interaction volume typically depends on the electron energy. A noise level can be added according to the dwell time at each raster position. Thereby, also a limited detection count of a selected detector geometry is considered. The imaging parameters can further depend on the material composition within the inspection volume of the wafer and can comprise a curtaining effect of a milling operation according to a material composition in the cross section to be milled. Curtaining effects are accessible to simple models of the milling operation and can thus be considered as well. Milling effects generate for example an additional topography contrast, superposed on the material contrast. The physical simulation can further consider additional structures within the inspection region, such as the word lines.

Alternatively, for emulating an image, a machine learning model can be trained based on reference images, e.g., layout files, as input and corresponding defect-free observed imaging datasets as output. In this way, the model learns to simulate the image acquisition and photolithography processes.

The observation representation of a subset of an imaging dataset can comprise spatial information regarding the location of the subset within the imaging dataset and/or the defect-free representation of a subset of a defect-free observed imaging dataset can comprise spatial information regarding the location of the subset within the defect-free observed imaging dataset and/or the representation of a subset of a reference image can comprise spatial information regarding the location of the subset within the reference image. For example, the spatial information can comprise positional encodings, in particular Fourier functions of different frequencies. In this way, spatial information can be taken into account in the defect detection method, thereby yielding results of higher accuracy. The location of a subset can, for example, include valuable information if typical types of defects mainly occur in specific regions, or if regions have a higher defect probability, e.g., border regions, or with respect to correlations of subsets from different imaging datasets or reference images.

In an example of the first or second embodiment of the disclosure, the subset comprises a single pixel. In this way, small sections of an imaging dataset of a wafer can be inspected for defects. Alternatively, the subset can comprise a number of pixels which are inspected together for defects. The observation representation of the subset of the imaging dataset can be obtained from a region of interest comprising the subset of the imaging dataset, and the defect-free representations of the subsets of the defect-free observed imaging datasets can be obtained from regions of interest comprising the subsets of the defect-free observed imaging datasets. This allows to take into account the context of the respective subset during defect detection, thereby increasing the accuracy of the method.

In an example of the first or second embodiment of the disclosure, a machine learning model is trained to assign a defect type from a predefined set of defect types to an observation representation of a subset of an imaging dataset of a wafer, the observation representation being based on the number of characteristic elements. In this way, a detected defect can also be classified allowing for a direct feedback to the user or to specific hardware units responsible for the kind of detected defect.

The imaging dataset of the wafer can be obtained via a charged particle beam system. A charged particle beam system includes, but is not limited to, a scanning electron microscope (SEM), a focused ion beam microscope, such as a Helium ion microscope. A further example of a charged particle beam system is a corrected electron scanning microscope, comprising a correction mechanism for correction of chromatic aberration and spherical aberration.

An example of the first or second embodiment of the disclosure further comprises directing an observation representation of a subset of an imaging dataset of a wafer and/or a defect-free representation of a subset of a defect-free observed imaging dataset and/or a reference representation of a reference image and/or characteristic elements and/or detected defects in an imaging dataset of a wafer to a display device or dashboard for visualization. An example of the first or second embodiment of the disclosure further comprises directing detected defects in an imaging dataset of a wafer to a display device or dashboard for visualization, wherein the detected defects are highlighted or labeled according to the type of defect. In this way, the usability is improved.

According to an example of the first or second embodiment of the disclosure, reference images, characteristic elements and/or the tolerance statistic is provided via an exchangeable hardware. In this way, this data can be reused in other applications and can be easily exchanged, thereby improving the usability of the methods.

An example of the first or second embodiment of the disclosure further comprises determining one or more measurements of the recognized defects in a subset of the imaging dataset of the wafer, in particular size, area, dimension, shape parameters, distance, radius, aspect ratio, type, number of defects, density, spatial distribution of defects, existence of any defects, etc.

Based on these measurements, the example can further comprise assessing the quality of the wafer based on the one or more measurements and at least one quality assessment rule, or the example can further comprise controlling at least one wafer manufacturing process parameter based on one or more measurements of the recognized defects in the imaging dataset of the wafer. Wafer manufacturing process parameters include the exposure time, the parameters of etching, deposition, implantation, thermal treatment and other processes involved during manufacturing, but are not limited to these parameters.

The disclosure also relates to a computer-readable medium, having stored thereon a computer program executable by a computing device, the computer program comprising code for executing a method according to any of the embodiments of the disclosure.

The disclosure also relates to a computer program product comprising instructions which, when the program is executed by a computer, cause the computer to carry out a method according to any of the embodiments of the disclosure.

The disclosure also concerns a system for controlling the quality of wafers produced in a semiconductor manufacturing fab, the system comprising: an imaging device adapted to provide an imaging dataset of a wafer; one or more processing devices; one or more machine-readable hardware storage devices comprising instructions that are executable by one or more processing devices to perform operations comprising a method for assessing the quality of a wafer.

The disclosure also involves a system for controlling the production of wafers in a semiconductor manufacturing fab, the system comprising: a mechanism for producing wafers controlled by at least one manufacturing process parameter; an imaging device adapted to provide an imaging dataset of a wafer; one or more processing devices; one or more machine-readable hardware storage devices comprising instructions that are executable by one or more processing devices to perform operations comprising a method for controlling at least one wafer manufacturing process parameter.

Any of the systems above can comprise a display device and/or a user interface.

While the examples and embodiments of the disclosure are described with respect to semiconductor wafers, it is understood that the disclosure is not limited to semiconductor wafers but can for example also be applied to reticles or masks for semiconductor fabrication or to other manufactured objects.

The disclosure described by examples and embodiments is not limited to the embodiments and examples but can be implemented by those skilled in the art by various combinations or modifications thereof.

### BRIEF DESCRIPTION OF THE DRAWINGS

FIG. 1 shows a photolithography process for manufacturing wafers;

FIG. 2 shows an inspection process for quality control of wafers;

FIGS. 3A-3D illustrate typical nuisances and defects in an imaging dataset of a wafer;

FIGS. 4A, 4B illustrate the difference between nuisance and defect;

FIGS. 5A-5D illustrate an inappropriateness of die-to-die methods for defect detection in imaging datasets of wafers;

FIG. 6 shows a flowchart illustrating the steps of a standard die-to-database approach;

FIG. 7 shows a flowchart illustrating the steps of the first embodiment of the disclosure;

FIG. 8 shows a flowchart illustrating the steps of the second embodiment of the disclosure;

FIG. 9 illustrates an example of the first embodiment of the disclosure;

FIG. 10 illustrates an example of the first embodiment of the disclosure;

FIG. 11 illustrates an example of the first embodiment of the disclosure;

FIG. 12 schematically illustrates a system, which can be used for controlling the quality of wafers produced in a semiconductor manufacturing fab; and

FIG. 13 schematically illustrates a system, which can be used for controlling the production of wafers in a semiconductor manufacturing fab.

### DETAILED DESCRIPTION

In the following, exemplary embodiments of the disclosure are described and schematically shown in the figures. Throughout the figures and the description, same reference numbers are used to describe same features or components. Dashed lines indicate optional elements.

Semiconductor manufacturing realizes 3D-template design onto physical materials at sub-nanometer scales. Imprinting is performed layer-by-layer, where each iteration consists of a manufacturing step based on photolithography and a quality control step.

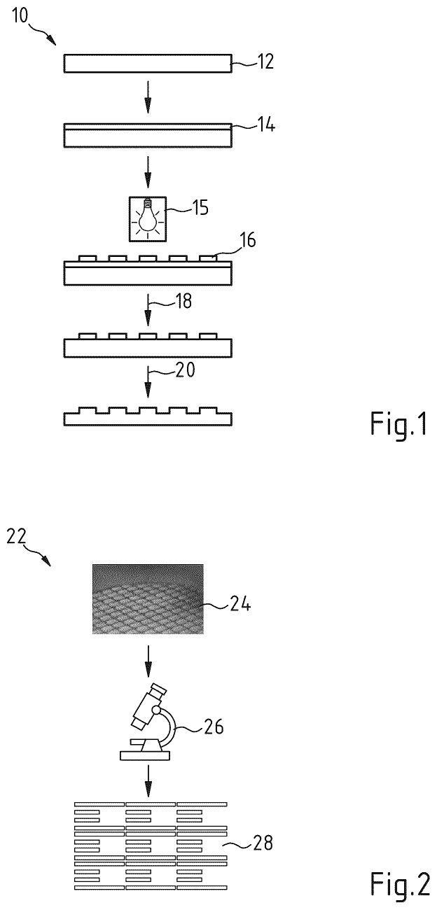

FIG. 1 shows the layered photolithography process 10 for manufacturing wafers 24. In each iteration, a photoresist 14 is deposited on a substrate 12. A mask 16 comprising a template of intended semiconductor patterns is used to selectively expose the photoresist 14 to destructive radiation 15. The substrate 12 underlying these areas is then removed by etching 18. The remaining photoresist 14 is finally removed by washing 20, thereby realizing the pattern of semiconductor structures specified by the mask 16.

FIG. 2 shows the inspection process 22 for quality control of each layer of a wafer 24. During manufacturing, the wafer 24 is imaged using a microscope 26 at a favorable resolution. The resulting imaging dataset 28 of the layer is examined for defects in the inspection process 22. The photolithography and inspection processes continue until all layers of the design are satisfactorily imprinted on the physical substrate.

The complex process of depositing, mask-exposure and etching can result in numerous abnormalities that can significantly reduce the yield of production. It is, therefore, desirable to detect defects in the imaging datasets 28 of wafers 24 in order to perform root-cause analysis and attribute the detected defects to specific steps of the manufacturing process. In this way, quality assurance and/or quality control mechanisms can be established. Quality assurance ensures that the approaches, techniques, methods and processes for wafer manufacturing are implemented according to the desired properties. It aims at improving parameters or conditions of the production process of the wafers 24 in the lab, e.g., deposition, exposure and etching processes. To this end, known and unknown defects are to be recognized and analyzed. In contrast, quality control aims at ensuring the quality of the final manufactured product in an in-line manufacturing process. To this end, known defects are to be recognized and analyzed.

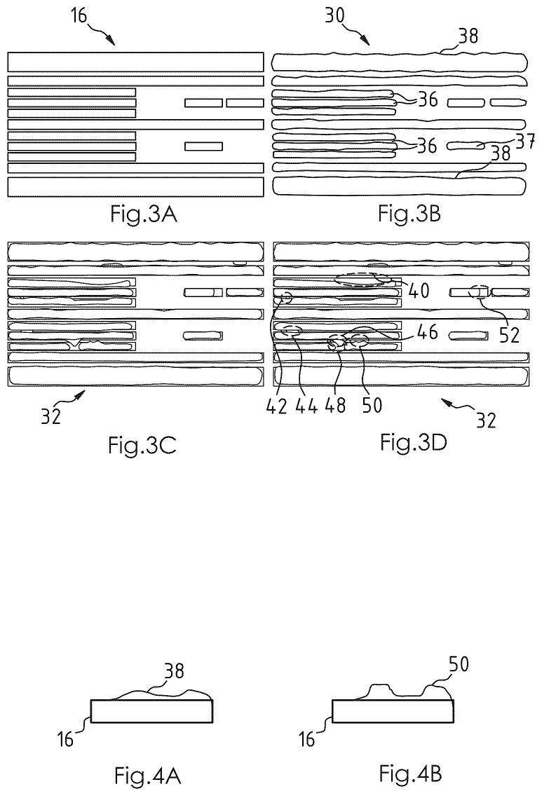

FIG. 3A to 3D illustrate typical nuisances 34 and defects 39 in an imaging dataset 28 of a wafer 24. FIG. 3A shows a mask 16 or layout image comprising ideal semiconductor structures of a layer in the form of polygons to be imprinted on a substrate 12 during wafer manufacturing. FIGS. 3B and 3C show an imaging dataset 28 of the wafer 24 generated during the inspection process 22 overlayed by the mask 16. In FIG. 3B the manufacturing process was defect-free yielding a defect-free observed imaging dataset 30. Yet, small deviations from the ideal layout cannot be prevented, e.g., line shortening 36, line thinning 37 and edge roughness 38. These random deviations do not affect the functionality of the wafer 24 and, therefore, belong to the class of nuisances 34. In FIG. 3C the manufacturing process was error-prone yielding an error-prone imaging dataset 32 comprising a number of defects 39 indicated in FIG. 3D, e.g., line thinning defects 40, bridge defects 42, long bridge defects 44, intrusion defects 46, line break defects 48, excursion defects 50 and line pullback defects 52. These defects 39 indicate problems in the manufacturing process, e.g., consistent line pullback defects 52 at the same structure at every die indicate a bug in the mask 16, bridge defects 42 are indicators of insufficient exposure and line thinning defects 40 are indicators of excessive etching 18. Other defects arise from defects or contamination from various sources, for example degeneration of lithography masks 16 or particle contamination. Such defects 39 are useful for root-cause analysis for quality assurance or quality control processes.

FIGS. 4A and 4B illustrate the difference between nuisance 34 and defect 39. FIG. 4A shows a portion of a mask 16 together with the realized design exhibiting edge roughness 38. This deviation belongs to the class of nuisances 34, since such deviations from the ideal design cannot be prevented and do not affect the functionality of the wafer 24. In contrast, FIG. 4B shows the same portion of the mask 16 together with the realized design, but with a larger structure outside the mask 16. Such a deviation is a defect 39 called excursion defect 50. To be able to make meaningful statements about the quality of a wafer 24, it is desirable to distinguish nuisances 34 from defects 39.

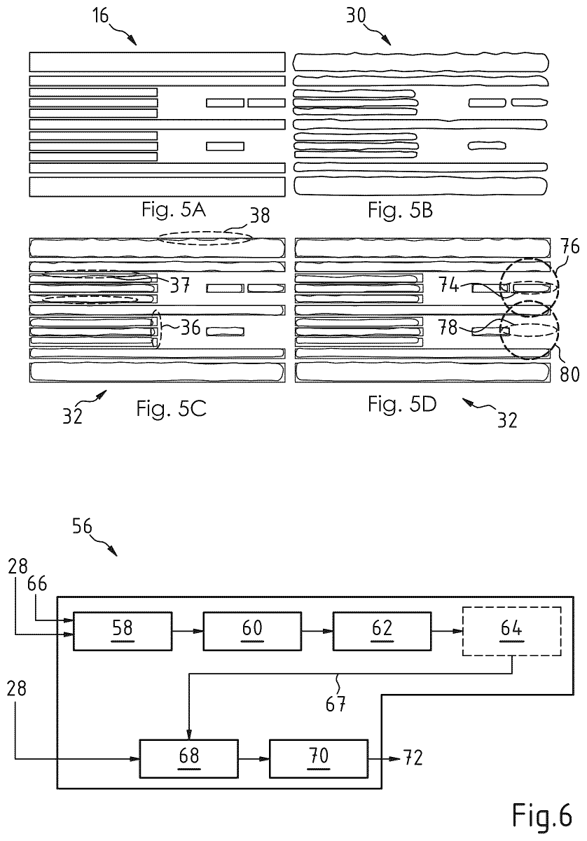

In order to detect defects 39 in imaging datasets 28 of wafers 24 popular approaches are die-to-die based analysis methods. Die-to-die methods compare portions of a wafer 24 with other portions of the same wafer 24 thereby discovering deviations from the typical or average wafer design. Such methods allow to distinguish between nuisances 34 and real defects 39 if trained with defect-free observed imaging datasets 30. Yet, a limitation of such methods is that defects 39 consistent across several dies, e.g., mask-related defects or regularly occurring defects, cannot be discovered. Yet, such defects 39 are especially relevant to detect. In addition, it is impossible to reason about defects 39 only based on a limited spatial context in an imaging dataset 28 as die-to-die methods do. FIG. 5 illustrates the inappropriateness of die-to-die methods for defect detection in imaging datasets 28 of wafers 24.

FIG. 5A shows a mask 16 or layout image comprising ideal semiconductor structures of a layer to be imprinted on a substrate during wafer manufacturing. FIGS. 5B and 5C show an imaging dataset 28 of the wafer 24 generated during the inspection process 22 overlayed by the mask 16. In FIG. 5B the manufacturing process was defect-free yielding a defect-free observed imaging dataset 30. Yet, as indicated in FIG. 5C, small deviations from the ideal layout cannot be prevented, e.g. line shortening 36, line thinning 37 at dense regions due to mask optics interaction during exposure, and edge roughness 38 due to the statistical nature of exposure and etching 18. Other differences can arise due to complicated registration problems between reference image 66 and observed image, e.g., due to non-linearities in the imaging process. Such random deviations do not affect the functionality of the wafer 24 and, therefore, belong to the class of nuisances 34. FIG. 5D illustrates the problem of reasoning about defects 39 based on only a local context 76, 80 of the semiconductor structures. Die-to-die methods derive their knowledge from similar structures in different locations of the same imaging dataset 28. Therefore, defects 39 which look like a correct structure in the imaging dataset cannot be detected. The same applies to defects 39 appearing in several locations of the imaging dataset 28. The markings 74, 78 indicate portions of defect-free semiconductor structures. Yet, if these structures are examined by a die-to-die method based on a local context 76, 80 only, it is impossible to tell if the structures are correct or not, since the local context of the structures looks exactly alike. For this reason, die-to-die methods are not suitable for a reliable defect detection in the inspection of semiconductor structures.

Instead, die-to-database approaches can be used. Die-to-database approaches compare portions of a wafer 24 with defect-free reference images 66, e.g., defect-free observed imaging datasets 30 of wafers 24 or generated images of wafers 24 such as simulated images or CAD-files, thereby discovering deviations from the ideal data.

FIG. 6 is a flowchart illustrating the steps of a standard die-to-database approach 56. The inputs of the approach are an observed imaging dataset 28 of a wafer 24 to be inspected and a reference image 66. The reference image 66 contains information about polygons and their spatial location representing ideal semiconductor structures, which can be compared to the observed imaging dataset 28. These polygons are rasterized onto an image grid in a rasterization step 58. In the following anchor point step 60 corresponding distinctive points are detected in the rasterized layout image and the imaging dataset 28. These anchor points are used for aligning the layout image and the imaging dataset 28 in an alignment step 62. The alignment of images can also be carried out or supported by human intervention. During an emulation step 64 the rasterized layout image can optionally be texturized to make it look like an observed image by simulating the image acquisition process, e.g., by a multibeam electron microscope, and the photolithography process 10. This emulated aligned image serves as an emulated aligned reference image 67, i.e., a model indicating the ideal semiconductor structures that should have been imprinted on the wafer 24. This emulated aligned reference image 67 is then compared to the observed imaging dataset 28 in a differencing step 68. The difference between the observed and the reference images highlights anomalies, that is defects 39 and nuisances 34 alike. To reduce the nuisances 34 among the detections the anomalies are post-processed in a post-processing step 70. For example, the anomalies can be presented to an expert who labels them as uninteresting nuisances 34 or interesting defects 39 yielding a number of defect proposals 72. This information can then be used for root-cause analysis.

Even though die-to-database approaches are more robust to defect detection, they cannot distinguish between nuisances 34 and real defects 39, and, therefore, use extensive post-processing.

An objective of this disclosure is, therefore, to propose a defect detection approach, which is at the same time robust to defect detection and distinguishes between nuisances 34 and real defects 39.

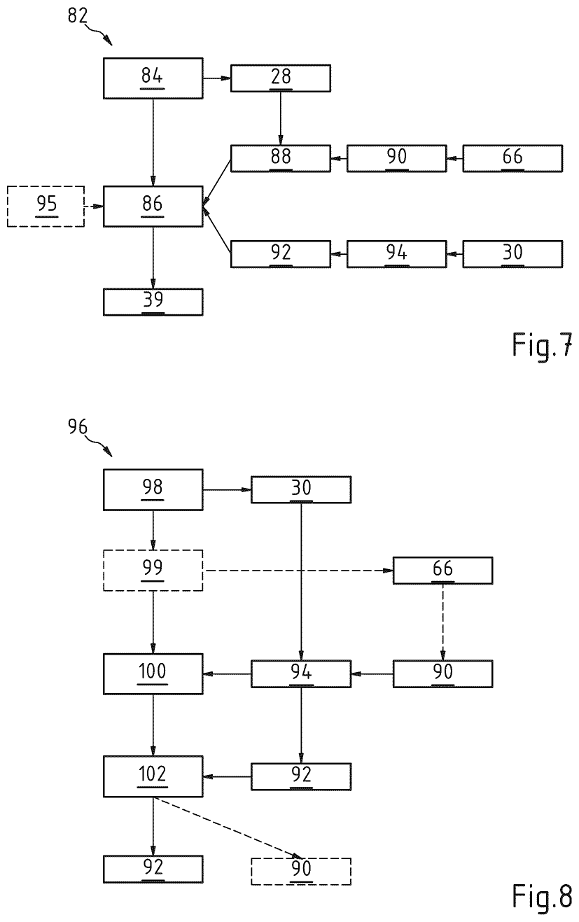

FIG. 7 shows a flowchart illustrating the steps of the first embodiment of the disclosure. The first embodiment involves a computer implemented method 82 for defect detection comprising the following steps: obtaining an imaging dataset 28 of a wafer 24 comprising semiconductor structures in an imaging step 84; in a defect criterion verification step 86, verifying a defect criterion for defect detection in a subset of the imaging dataset 28 of the wafer 24, the defect criterion comprising an observation representation 88 of the subset of the imaging dataset 28 with respect to a number of characteristic elements 90 derived from reference images 66 of semiconductor structures, wherein the observation representation and the characteristic elements 90 define a reconstruction of minimal reconstruction error of the subset of the imaging dataset; and a tolerance statistic 92 on defect-free representations 94 of subsets of defect-free observed imaging datasets 30 of wafers 24, wherein each of the defect-free representations and the characteristic elements 90 define a reconstruction of minimal reconstruction error of the subset of the defect-free imaging dataset. The method generates defect information for the subset of the imaging dataset 28 based on the defect criterion. The detected defects 39 can be used for quality assurance or quality control of wafers.

It can be desirable for the reference images 66 to be aligned reference images or emulated aligned reference images 67 as described with respect to FIG. 6. It can be desirable for the reference images 66 and the defect-free observed imaging datasets 30 to comprise the same semiconductor structures as the imaging dataset 28 of the wafer 24 to be inspected.

An observation representation 88 of a subset of an imaging dataset 28 can be obtained by solving the following general optimization problem

$$\overline{r} = {argmin}_{r} {E}_{C} ( r , x ) , \qquad ( I )$$

with r indicating an observation representation 88 of the subset x of an imaging dataset 28, which minimizes a reconstruction error E_{c} with respect to a number of characteristic elements C.

The optimization problem can comprise at least one constraint or prior on an observation representation 88. For example, the constraint or prior can be a measure of sparsity of the observation representation 88, in particular the L0-norm or the L1-norm or the kurtosis of the observation representation 88.

For example, equation (I) can further be restricted by a prior as follows

$$\overline{r} = {argmin}_{r} ( {E}_{C} ( r , x ) + λ q ( r ) ) ,$$

where q is a prior on r, e.g., the L1-norm, and λ a weighting factor.

For example, equation (I) can further be restricted by a constraint as follows

$$\overline{r} = {argmin}_{r} {E}_{C} ( r , x ) , s . t . r ∈ {ℛ}^{'}$$

with, for example, [symbol] ={rᵢ∈ [symbol] |∥rᵢ∥₁≤v} with v being a predefined value.

The tolerance statistic 92 can be used in different ways by the defect criterion, for example as a direct indicator of the defect information, e.g., a defect probability, or as a prior in the optimization problem (I) above. Other uses of the tolerance statistic 92 are conceivable.

The first option uses the tolerance statistic 92 as a direct indicator of a defect 39. In an example of the first embodiment of the disclosure, the defect criterion comprises detecting a defect 39 in the subset of the imaging dataset 28 based on a statistical property of the obtained observation representation 88 with respect to the tolerance statistic 92.

Let P, for example, indicate a probability distribution estimated from the samples of the tolerance statistic 92, i.e., the defect-free representations 94 of subsets of defect-free observed imaging datasets 30 with respect to the number of characteristic elements. Then the probability distribution P can be used to assign a defect-probability to the observation representation F of a subset of an imaging dataset 28, i.e.

$$P ( \overline{r} ) , where \overline{r} = {argmin}_{r} {E}_{C} ( r , x ) .$$

The tolerance statistic 92 can also be used directly without estimating a probability distribution from the samples first, e.g., by computing the relative frequency of an observation representation 88, for example based on a histogram.

Instead of deriving a defect-probability, a binary decision for ‘defect’/‘not defect’ can also be obtained. To this end, the statistical property can, for example, comprise a quantile of the tolerance statistic 92, in particular a threshold.

Let F be the cumulative distribution function of a probability density function estimated from a number of defect-free representations 94 of defect-free observed imaging datasets 30 of the tolerance statistic 92, then xₚ is a p-quantile if

$$F ( {x}_{p} ) \geq p and {lim}_{t \to {x}_{p}} F ( t ) \leq p .$$

An empirical p-quantile can also be estimated from a number of defect-free representations 94 x₁, . . . ,xₙ of the tolerance statistic without estimating a cumulative distribution function first. X (p) is an empirical p-quantile if for at least p·n defect-free representations holds

$${x}_{i} \leq {x}_{( p )}$$

and for at least (1−p)·n defect-free representations holds

$${x}_{i} \geq {x}_{( p )} .$$

The quantile xₚ Or x₍ₚ₎ can be used as a threshold separating the fraction p of representations with high likelihood from the fraction (1−p) of representations with low likelihood, i.e. outliers, according to the tolerance statistic 92. For a given threshold xₚ the corresponding p-value can also be determined.

Quantiles can be determined only for a subset of the dimensions of the defect-free representations 94, in particular for a single dimension, or for each dimension separately. Accordingly, thresholds can be a vector of thresholds for a subset of the dimensions of the defect-free representations 94, in particular a single value for a single dimension only. Based on a quantile or threshold an observation representation 88 of a subset of an imaging dataset 28 can be marked as a defect 39, e.g., if the corresponding value of the observation representation 88 exceeds the quantile xₚ or threshold xₚ:

$$\overline{r} > {x}_{p} where \overline{r} = {argmin}_{r} {E}_{C} ( r , x ) .$$

In an example of the first embodiment of the disclosure, the statistical property of the tolerance statistic 92 comprises a confidence interval. The confidence interval can be determined by fitting a probability density function to the defect-free representations 94. If the observation representation 88 of the subset of the observed imaging dataset 28 lies outside the confidence interval, the observation representation 88 and, thus, the corresponding subset of the imaging dataset 28, is an outlier with respect to the tolerance statistic 92 and marked as a defect 39. Again, confidence intervals can be determined for a subset of the dimensions of the defect-free representations 94, in particular for a single dimension, or for each dimension separately. Let [bₗ, bᵤ] denote a confidence interval with lower limit bₗ and upper limit bᵤ, then a subset of an imaging dataset 28 is assigned the label ‘defect’, if its representation r lies outside the confidence interval

$$\overline{r} ∉ [ {b}_{l} , {b}_{u} ] where \overline{r} = {argmin}_{r} {E}_{C} ( r , x ) .$$

In an example of the first embodiment of the disclosure, the statistical property comprises a moment of the tolerance statistic 92, in particular a mean value u and/or a variance σ. For example, a Gaussian distribution can be fitted to the defect-free representations 94 and a confidence interval can be obtained based on the statistical mean and variance of the defect-free representations 94, e.g., bₗ=μ−3σ, bᵤ=μ+3σ.

Alternatively, a distance of the observation representation 88 of a subset of an observed imaging dataset 28 from the mean can be used as defect-indicator.

The second option uses the tolerance statistic 92 as a prior in the optimization problem for obtaining an observation representation 88 of a subset of an imaging dataset 28. The optimization problem, thus, contains a prior comprising the tolerance statistic on defect-free representations 94. For example, the optimization problem can be formulated in the following way, e.g., based on the optimization problem (I) above:

$$\overline{r} = {argmin}_{r} ( {E}_{C} ( r , x ) - γ ln P ( r ) )$$

where γ is a weighting factor. The tolerance statistic 92 P is formulated as a log likelihood function in this case. Other terms of the optimization problem comprising the tolerance statistic 92 are conceivable, e.g., the formulation with respect to a one-class SVM as described below. The tolerance statistic 92 on defect-free representations 94 of defect-free observed imaging datasets 30 can also be defined or modified by a human.

In an example of the first embodiment of the disclosure, the defect criterion comprises detecting a defect 39 in the subset of the obtained imaging dataset 28 based on the reconstruction error of the solution to the optimization problem. Since the characteristic elements 90 are derived from reference images 66 without defects 39, they do not represent defects 39 well. Therefore, the observation representation 88 of the subset of the imaging dataset 28 with respect to the characteristic elements 90 deviates from the original subset x in case the subset contains defects, which cannot be represented by the characteristic elements 90. Thus, the reconstruction error of the observation representation 88 with respect to the characteristic elements 90 serves as defect information in form of a defect indicator D:

$$D ( x ) = {E}_{C} ( \overline{r} , x ) where \overline{r} = {argmin}_{r} ( {E}_{C} ( r , x ) - γ ln P ( r ) )$$

D can also be a binary function by applying a threshold to the reconstruction error.

The reconstruction error can, for example, be measured by an Lp norm, e.g. an L1 or L2 norm, or a weighted Lp norm:

$${E}_{C} ( \overline{r} , x ) = {\vert w ( x ) ( {R}_{C} ( x ) - x ) \vert}_{{L}_{p}}$$

where R_{c}(x) is the reconstruction of x with respect to the characteristic elements C and w (x) denotes a weight or a vector of weights. Various reconstructions of x with respect to a number of characteristic elements C are described below.

An example of the first embodiment of the disclosure can be combined with other methods for defect detection, e.g., a method illustrated in FIG. 6. To this end, the defect criterion can further comprise modifying the defect detection result via a trained machine learning model 95 as indicated by the dashed lines in FIG. 7. The defect information generated from the defect criterion can, for example, be combined with the output of the machine learning model, e.g., the defect probabilities can be multiplied, or the subset is only labeled as defect if both methods assign the label ‘defect’ to the subset, or, to obtain a more sensitive method, the subset is labeled as ‘defect’ if one of the methods assigns the label ‘defect’ to the subset.

The machine learning model 95 can also be used to modify an intermediate result of the defect detection method according to an example of the first embodiment of the disclosure, thereby post-processing the intermediate result. The improved intermediate result can then be processed further by the defect detection method. For example, an observation representation 88 of a subset of an imaging dataset 28 of a wafer 24 can be modified by a machine learning model trained to suppress nuisances 34, e.g., by reducing the length of a registration vector or reducing a difference between grey values.

The trained machine learning model 95 can, for example, comprise a defect detection, anomaly detection, defect segmentation or anomaly segmentation approach. Anomalies refer to deviations of semiconductor structures from a predefined norm. They include defects 39 and nuisances 34 alike.

The trained machine learning model 95 can, for example, be applied to the subset of the imaging dataset 28 of the wafer 24 and/or to a difference of the subset of the imaging dataset 28 of the wafer 24 and an aligned reference image 67, in particular an emulated aligned reference image 67, and/or to the reconstruction error of the observation representation 88 of the subset of the imaging dataset 28 of the wafer. Instead of aligning the reference image 66, the machine learning model 95 can also learn to render the reference image 66 to fit the image distribution of the imaging dataset 28. The trained machine learning model 95 can also use a region of interest comprising the subset of the imaging dataset 28 of the wafer 24 and/or a region of interest comprising the difference of the subset and the reference image 66 and/or a region of interest comprising the reconstruction error of the observation representation 88 of the subset of the imaging dataset 28 of the wafer 24 as input. In this way, the machine learning model 95 learns to suppress nuisances 34 while retaining defects 39.

For training the machine learning model 95, a number of user annotated samples of defects 39, nuisances 34 and defect-free data can be presented to the machine learning model 95. The samples do not have to cover all types of defects 39 or nuisances 34, since the machine learning model 95 generalizes to unknown defects 39 and nuisances 34.

The trained machine learning model can comprise an autoencoder. Autoencoders learn the expected statistical variation of defect-free observed imaging datasets 30. An autoencoder can be trained using subsets of defect-free observed imaging datasets 30 and corresponding subsets of reference images 66 and/or differences thereof or reconstruction errors thereof with respect to characteristic elements 90 or regions of interest comprising the input data. The autoencoder learns a compressed representation of the input data. If a subset of an observed imaging dataset 28 of a wafer 24 has no defects 39, the subset is reconstructed with high fidelity by the autoencoder. However, if the subset contains defects 39, corresponding spatial regions are reconstructed with reduced fidelity. Defects 39 can then be detected by computing the reconstruction error of the output of the autoencoder with respect to the input of the autoencoder.

According to an aspect of the example of the first embodiment of the disclosure, the trained machine learning model 95 can comprise a segmentation model. A defect 39 obtained by a method according to an example of the first embodiment of the disclosure can be compared to the result of the segmentation model and labeled based on a combination of both results.

FIG. 8 shows a flowchart illustrating the steps of the second embodiment of the disclosure. The second embodiment concerns a computer implemented method 96 for obtaining a tolerance statistic 92 on defect-free representations 94 of subsets of defect-free observed imaging datasets 30 of wafers 24 based on a number of characteristic elements 90 derived from reference images 66 of semiconductor structures, comprising the following steps: obtaining defect-free observed imaging datasets 30 of wafers 24 comprising semiconductor structures in an imaging step 98; generating defect-free representations 94 of subsets of defect-free observed imaging datasets 30 of wafers 24 with respect to a number of characteristic elements 90 derived from reference images 66 of semiconductor structures, wherein each of the defect-free representations 94 and the characteristic elements 90 define a reconstruction of minimal reconstruction error of a subset of the defect-free observed imaging datasets 30 in a representation generation step 100, and obtaining a tolerance statistic 92 on the defect-free representations 94 in a tolerance statistic step 102. The tolerance statistic 92 can be used for defect detection of wafers, e.g., to carry out a method of any example of the first embodiment of the disclosure or for quality assurance or quality control of wafers. It can be desirable for the defect-free observed imaging datasets 30 to comprise the same semiconductor structures as the imaging dataset 28 of the wafer 24 to be inspected.

An example of the second embodiment of the disclosure can further comprise a characteristic element step 99 before the representation generation step 100, therein obtaining the number of characteristic elements 90 from reference images 66 of semiconductor structures, e.g., from emulated registered reference images 67 comprising the same semiconductor structures, by solving an optimization problem comprising a minimal reconstruction error of reconstructions of reference images 66, the reconstructions being defined by reference representations 104 and the characteristic elements 90. Alternatively, the characteristic elements 90 can be obtained from another source, e.g., from a previous use-case or from a database or they can be loaded from memory.

It can bed desirable for the accuracy of the methods for the reference images 66 to be aligned before deriving the characteristic elements 90. The alignment process described with reference to FIG. 6 can be used here as well, e.g., using rasterization, anchor points, alignment or registration techniques or human intervention. It is also beneficial if the reference images 66 are emulated, i.e. the texture of the reference images 66 is adapted to make them look similar to observed imaging datasets 28 as described with reference to FIG. 6 above. It can be desirable for the reference images 66 to comprise the same semiconductor structures as the imaging dataset 28 of the wafer 24 to be inspected.

The optimization problem for obtaining the characteristic elements C can generally be formulated in the following way:

$$\overline{C} = {argmin}_{C ∈ 𝒞 , r ∈ ℛ} {\sum }_{i = 1}^{n} {E}_{C} ( {r}_{i} , {x}_{i} ) \qquad ( II )$$

According to an example of the second embodiment, the optimization problem comprises at least one constraint or prior on a characteristic element 90. For example, the constraint or prior can involve an Lp-norm of the characteristic element 90, in particular the L0-norm or the L1-norm of the characteristic element 90.

The optimization problem comprising a constraint on a characteristic element 90 can be formulated based on a set [symbol] as follows

$$\overline{C} = {argmin}_{C ∈ 𝒞 , r ∈ ℛ} {\sum }_{i = 1}^{n} {E}_{C} ( {r}_{i} , {x}_{i} ) , s . t . {C}_{i} ∈ {𝒞}^{´} ,$$

for example with [symbol] {Cᵢ∈ [symbol] |Cᵢ℄_{L}_{ₚ}=v}, where v is a predetermined value, e.g. 1.

The optimization problem comprising a prior q on a characteristic element 90 can be formulated with a tunable weight/as follows

$$\overline{C} = {argmin}_{C ∈ 𝒞 , r ∈ ℛ} {\sum }_{i = 1}^{n} {E}_{C} ( {r}_{i} , {x}_{i} ) + λ q ( {C}_{i} ) .$$

The prior here functions as a regularizer on the characteristic elements 90, e.g., q(Cᵢ)=|Cᵢ|_{L}_{ₚ}.

According to an example of the first or second embodiment of the disclosure, the optimization problem comprises at least one constraint or prior on a reference representation 104. For example, the constraint or prior can involve an Lp-norm of a reference representation 104, in particular the L2-norm or the L1-norm or the L0-norm or the kurtosis.

For example, equation (I) can further be restricted by a prior as follows

$$\overline{r} = {argmin}_{r} ( {E}_{C} ( r , x ) + λ q ( r ) ) ,$$

where q is a prior on r, e.g., the L1-norm, and λ a weighting factor.

For example, equation (I) can further be restricted by a constraint as follows

$$\overline{r} = {argmin}_{r} {E}_{C} ( r , x ) , s . t . r ∈ {ℛ}^{´}$$

with, for example, [symbol] ={rᵢ∈ [symbol] | ∥rᵢ∥1≤v} with v being a predefined value.

For example, the optimization problem in equation (II) for obtaining the characteristic elements 90 can further be restricted by a constraint on a reference representation 104 as follows

$$\overline{C} = {argmin}_{C ∈ 𝒞 , r ∈ ℛ} {\sum }_{i = 1}^{n} {E}_{C} ( {r}_{i} , {x}_{i} ) , s . t . {r}_{i} ∈ {ℛ}^{´} .$$

with, for example, [symbol] ={rᵢ∈ [symbol] | ∥rᵢ∥₂²≤v} or [symbol] ={rᵢ∈ [symbol] ∥rᵢ∥₁≤v}, for a specified value v.

For example, the optimization problem in equation (II) for obtaining the characteristic elements 90 can further be restricted by a prior q on a reference representation 104 and a weighting factor λ as follows:

$$\overline{C} = {argmin}_{C ∈ 𝒞 , r ∈ ℛ} {\sum }_{i = 1}^{n} {E}_{C} ( {r}_{i} , {x}_{i} ) + λ q ( {r}_{i} ) .$$

The prior here functions as a regularizer on the reference representation 104 and could be formulated, e.g., as

$$q ( {r}_{i} ) = {‖ {r}_{i} ‖}_{2}^{2} or q ( {r}_{i} ) = {‖ {r}_{i} ‖}_{1} or q ( {r}_{i} ) = {‖ {r}_{i} ‖}_{0} .$$

In an example of the first or second embodiment of the disclosure, the constraint or prior involves an Lp-norm of the gradient of reference representations 104 of neighboring subsets of reference images, in particular the L2-norm or the L1-norm, e.g.,

$${ℛ}^{´} = \{ {r}_{i} ∈ ℛ \vert {\vert ∇ {r}_{i} \vert}_{{L}_{p}} \leq v \} or q ( {r}_{i} ) = {\vert ∇ {r}_{i} \vert}_{{L}_{p}} .$$

For example, equation (I) can further be restricted by a prior as follows

$$\overline{r} = {argmin}_{r} ( {E}_{C} ( r , x ) + λ {\vert ∇ {r}_{i} \vert}_{{L}_{p}} ) ,$$

In an example of the first or second embodiment of the disclosure, the constraint or prior is a measure of sparsity of the reference representation 104, in particular the L0-norm or the L1-norm or the kurtosis of the reference representation 104.

In an example, the optimization problem can take the following form

$$\overline{C} = {argmin}_{C ∈ 𝒞 , r ∈ ℛ} {\sum }_{i = 1}^{n} {E}_{C} ( {r}_{i} , {x}_{i} ) + λ {‖ {r}_{i} ‖}_{1} s . t . {C}_{i} ∈ \{ {C}_{i} ∈ 𝒞 \vert {‖ {C}_{i} ‖}_{2} = 1 \} .$$

According to an example of the first or second embodiment of the disclosure, the tolerance statistic 92 comprises a probability density function obtained from the defect-free representations 94 of defect-free observed imaging datasets 30 by a density estimation technique.

The tolerance statistic can comprise a joint probability density function f (S,R) or a conditional probability density function f (S|R) obtained by a density estimation technique, wherein S comprises observation representations 88 of subsets of observed imaging datasets 28 and/or defect-free representations 94 of subsets of defect-free observed imaging datasets 30, and wherein R comprises reference representations 104 of subsets of reference images 66 with respect to a number of characteristic elements 90, e.g., the same number of characteristic elements 90 or an additional number of characteristic elements 91. In this way, rare semiconductor structures or rare nuisances 34 can be modeled by the probability density function without having probabilities close to 0, thus improving the accuracy of the method. The representations 88, 94, 104 can, thereby, be derived based on different sets of characteristic elements. For example, a number of additional characteristic elements 91 can be derived from observed imaging datasets 28 and/or defect-free observed imaging datasets 30. Then the reference representations 104 R of reference images 66 can be based on the characteristic elements 90 and the representations S comprising observation representations 88 of observed imaging datasets 28 and/or defect-free representations 94 of defect-free observed imaging dataset 30 can be based on the additional characteristic elements 91, or vice versa.

For density estimation, parametric or non-parametric methods can be used. For example, the probability density function of the tolerance statistic can be obtained by a parametric density estimation technique, in particular the probability density function of a Gaussian or a Gaussian mixture model 92. Alternatively, the probability density function of the tolerance statistic 92 can be obtained by a non-parametric density estimation technique, in particular a Parzen density estimator. The tolerance statistic 92 can also comprise a machine learning model trained on the defect-free representations 94, in particular a one-class SVM or an SVDD.

According to an aspect of the example, the tolerance statistic 92 comprises only a subset of the dimensions of the defect-free representation 94. In particular, the tolerance statistic 92 can comprise only a single dimension of the defect-free representations 94. The tolerance statistic 92 can also comprise a separate tolerance statistic 92 for each dimension of the subset of dimensions of the defect-free representations 94.

In an example of the first or second embodiment of the disclosure, the observation representation 88 of the subset of the imaging dataset 28 comprises a registration vector indicating the offset between the subset of the imaging dataset 28 and a characteristic element 90 in the form of a corresponding subset of a reference image 66, such that the corresponding subset of the reference image 66 is registered with the subset of the imaging dataset 28 via the registration vector, and wherein the defect-free representations 94 of the subsets of the defect-free observed imaging datasets 30 comprise registration vectors indicating the offset between the subsets of the defect-free observed imaging datasets 30 and characteristic elements 90 in the form of corresponding subsets of reference images 66, such that the corresponding subsets of the reference images 66 are registered with the subsets of the defect-free observed imaging datasets 30 via the registration vectors. In this example, the characteristic elements 90 can be understood as corresponding sections of reference images 66, which are registered with the subsets. Based on the registration vectors and the tolerance statistic 92 on these registration vectors, defects 39 can be detected.

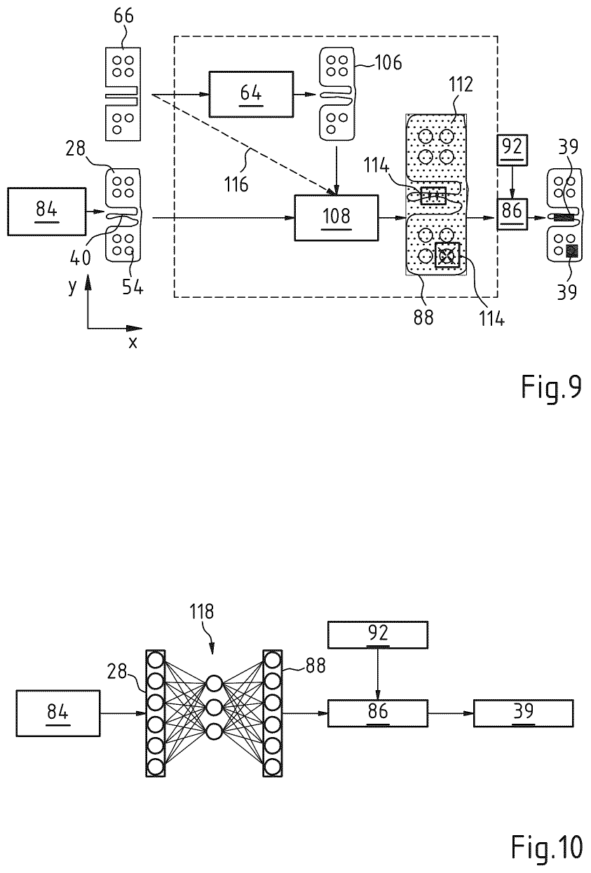

FIG. 9 illustrates an example of the first embodiment of the disclosure. In an imaging step 84 a subset of an imaging dataset 28 of a wafer 24 is obtained, which is to be checked for defects 39. The imaging dataset 28 contains a line thinning defect 40 and a spurious structure defect 54. The corresponding reference image 66 comprising the correct semiconductor layout is first emulated in an emulation step 64, yielding an emulated reference image 106. The emulation is optional 116. The emulated reference image 106, or respectively the reference image 66 without emulation, is registered with the subset of the imaging dataset 28 in a registration step 108, for example via a machine learning registration approach or based on an optimization problem for minimizing the reconstruction error. To this end, the reconstruction error can comprise the warping error between the subset and the corresponding subset of the reference image 66 or vice versa, e.g.,

$${E}_{C} ( r , x ) = {\vert x - c \vert}_{{L}_{p}} , where {I}_{O} ( a ) = x , c = {I}_{ref} ( a + r ) ,$$

where Iₒ(a) denotes a subset of an observed imaging dataset at location a, and I_{ref}(a+r) denotes a reference image 66 at location a+r. For example, observation representations 88 comprising registration vectors, i.e. a registration vector field, can be obtained by solving an optimization problem comprising a warping error and a regularizer on the registration vector field:

$$arg {min}_{{r}_{i} ∈ {ℝ}^{2}} \{ {\sum }_{i = 1}^{n} {\vert {x}_{i} - {c}_{i} \vert}^{2} + λ \vert ∇ {r}_{i} \vert \vert {I}_{O} ( {a}_{i} ) = {x}_{i} , {c}_{i} = {I}_{ref} ( {a}_{i} + {r}_{i} ) \} .$$

A tolerance statistic 92 of registration vectors is obtained from registration vectors of defect-free observed imaging datasets 30. Based on this tolerance statistic 92 defect information is generated for the computed registration vectors in the defect criterion verification step 86. For example, zero offset registration vectors 112 indicate no defect or a low defect probability, whereas non-zero offset registration vectors 114 indicate a defect 39 or a high defect probability. The registration vectors can be directed from a subset in a reference image 66 to a corresponding subset of an observed imaging dataset 28 or, vice versa, from a subset of an observed imaging dataset 28 to a corresponding subset of a reference image 66. Instead of computing the tolerance statistic 92 from registration vectors of defect-free observed imaging datasets 30, the tolerance statistic 92 can be defined by a human, e.g., a defect probability can be assigned according to the length of the registration vectors, or a minimum length can be defined as a threshold, e.g., zero offset registration vectors 112 indicating no defect, whereas non-zero offset registration vectors 114 surpassing the minimum length indicate a defect 39.

In an example of the first or second embodiment of the disclosure, the number of characteristic elements 90 comprises a machine learning model, in particular a neural network 118 comprising an autoencoder, trained on the reference images 66 of semiconductor structures, and the observation representation 88 of a subset of an imaging dataset 28 comprises the output of the machine learning model applied to the subset of the imaging dataset 28. Each defect-free representation 94 of a subset of a defect-free observed imaging dataset 30 comprises the output of the machine learning model applied to the subset of the defect-free observed imaging dataset 30 FIG. 10 illustrates an example of the first embodiment of the disclosure. The machine learning model, e.g., the neural network 118, decodes a subset of an imaging dataset 28 of a wafer 24 obtained in an imaging step 84, thereby obtaining an observation representation 88 of the subset with, e.g., the following reconstruction error

$${E}_{C} ( r , x ) = {\vert x - r \vert}_{{L}_{p}} , where r = C ( x ) .$$

C (x) is the output of the machine learning model applied to the input x. i.e., the subset of the imaging dataset 28. The machine learning model is trained by solving an optimization problem, e.g., a neural network 118 is trained to minimize the reconstruction error of subsets of reference images 66. Further constraints can be imposed on the machine learning model. A tolerance statistic 92 can be derived from defect-free representations 94, i.e., from the output of the machine learning model applied to subsets of defect-free observed imaging datasets 30. Based on this tolerance statistic 92, a subset of an observed imaging dataset 28 can be assigned a label ‘defect’ or ‘no defect’ or a defect probability in the defect criterion verification step 86, thereby generating defect information.

The neural network 118, can, for example, comprise an autoencoder. Autoencoders learn a compressed internal representation of the defect-free reference images 66. As a result, the model is capable of perfectly reconstructing defect-free reference images 66. In contrast, defect-free observed imaging datasets 30 comprising nuisances 34 as well as defective subsets of observed imaging datasets 28 are not fully reconstructed. However, nuisances 34 can be distinguished from defects 39 based on the tolerance statistic 92.

In an example of the first or second embodiment of the disclosure, the observation representation 88 of the subset of an imaging dataset 28 comprises coefficients of a decomposition 120 of the subset of the imaging dataset 28 with respect to the number of characteristic elements 90, and wherein the defect-free representations 94 of the subsets of the defect-free observed imaging datasets 30 comprise coefficients of decompositions 120 of the subsets with respect to the number of characteristic elements 90. Let x∈ [symbol] indicate the vectorized subset of the imaging dataset 28 of width w and height h and let C∈ [symbol] be a matrix comprising n characteristic components of size w·h and let r∈ [symbol] . Then the reconstruction error measures the deviation of the subset from its decomposition 120, for example:

$${E}_{C} ( r , x ) = {\vert x - C \cdot r \vert}_{{L}_{p}} .$$

The observation representation 88 of a subset can be obtained by solving, for example, the following optimization problem

$$\overline{r} = {argmin}_{r} \{ {\vert x - C \cdot r \vert}_{{L}_{p}} + λ {\vert r \vert}_{1} \} .$$

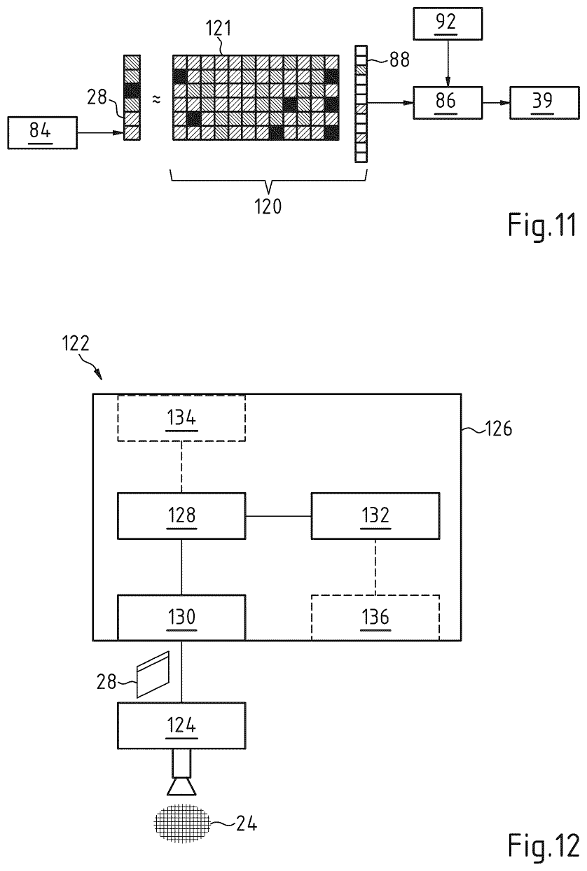

FIG. 11 illustrates an example of the first embodiment of the disclosure. The characteristic elements comprise a dictionary 121 obtained by dictionary learning. For the observation representation 88 of a subset of an imaging dataset 28 acquired in an imaging step 84 defect information can be generated. To this end, the subset is decomposed with respect to the dictionary elements obtaining an observation representation 88 comprising coefficients of the decomposition 120. Based on a tolerance statistic 92 obtained from defect-free representations 94 of defect-free observed imaging datasets 30, defects 39 can be detected in a defect criterion verification step 86, e.g., by using the tolerance statistic P as a direct defect indicator

$$P ( \overline{r} ) where \overline{r} = {argmin}_{r} \{ {\vert x - C \cdot r \vert}_{{L}_{p}} + λ {\vert r \vert}_{1} \}$$

or by using the tolerance statistic P as a prior, for example by

$$\overline{r} = {argmin}_{r} \{ {\vert x - C \cdot r \vert}_{{L}_{p}} + λ {\vert r \vert}_{1} - γ ln P ( r ) \}$$

and using the reconstruction error E_{c}(r, x)=|x−C.r|_{L}_{ₚ} as defect indicator.

In an example of the first or second embodiment of the disclosure, instead of using the observed imaging datasets themselves, the methods can directly operate on the difference of subsets of observed imaging datasets and the corresponding subsets of reference images. In this way, only the difference image is to be processed, which contains a lot less information than the observed imaging datasets. This reduces the complexity of the model, i.e., the decomposition, the characteristic elements and the representations, thus increasing the accuracy of the methods. In an example of the first or second embodiment of the disclosure, therefore, the number of characteristic elements 90 and the tolerance statistic 92 are derived from difference images of subsets of defect-free observed imaging datasets 30 and aligned subsets of reference images 66, and the observation representation 88 of a subset of an imaging dataset 28 comprises coefficients of a decomposition 120 of a difference image of the subset and an aligned reference image with respect to the number of characteristic elements 90, and the reconstruction error measures the deviation of the subset from its decomposition 120.

The decomposition 120 can be linear or non-linear. For example, the characteristic elements 90 can comprise elements of a basis, e.g., of a wavelet basis or a Fourier basis. The characteristic elements 90 can also comprise a number of principal components obtained via principal component analysis, e.g., a subset of the principal components. The characteristic elements 90 can comprise an overcomplete frame. The characteristic elements 90 can comprise a dictionary 121 obtained via dictionary learning.

The dictionary C 121 can be learned from subsets of reference images 66 x₁, . . . , xₖ, in particular emulated aligned reference images 67, by solving, for example, the following optimization problem

$$C = {argmin}_{C , {r}_{i} ∈ {ℝ}^{n}} {\sum }_{i = 1}^{k} {‖ C \cdot {r}_{i} - {x}_{i} ‖}_{2}^{2} + λ \cdot {\vert {r}_{i} \vert}_{1} , s . t . ‖ {C}_{i} ‖ = 1 ,$$

The L1-norm of the reference representations 104 enforces a sparse reconstruction of the subset x with respect to the dictionary elements, called atoms, that is a reconstruction with few non-zero elements, i.e., a linear combination of only a few atoms. This prevents subsets with defects 39 from being nearly reconstructed based on a combination of many different atoms, thus making sure that a large reconstruction error remains for these subsets, so they are labeled as ‘defect’. In this way, the accuracy of the defect detection method is improved.

The elements of the dictionary 121 are constrained to have unit norm, so that any scaling is contained in the reference representation 104. Without this constraint, the additional regularization of the reference representation norm would be effectless, because scaling could be contained in the dictionary 121 and the reference representation norm could become arbitrarily small.

Since optimizing the dictionary 121 and the reference representations r$104 at the same time is a non-convex problem, an alternating optimization technique can be employed. To this end, the problem is separated into a) updating the dictionary 121 for fixed reference representations 104 and b) refining the reference representations 104 given an updated dictionary 121. Both problems are solved using the alternate direction method of multipliers (ADMM) in an alternating way. In case of optimizing the dictionary elements, a constrained version of ADMM can be used in order to handle the constraint on the dictionary elements (unit or bounded norm), which amounts to projecting onto the feasible set between each two iterations.

For computing observation representations 88 of subsets of an imaging dataset 28 based on a given dictionary 121, the optimization technique depends on the optimization problem.

In case the tolerance statistic P is used as a direct defect indicator

$$P ( \overline{r} ) where \overline{r} = {argmin}_{r} \{ {\vert x - C \cdot r \vert}_{{L}_{p}} + λ {\vert r \vert}_{1} \}$$

ADMM can be used for optimization.

In case the tolerance statistic P is used as a prior in the optimization problem and the prior comprises a one-class SVM, gradient descent steps are to be carried out for the one-class SVM. To this end, a generalized proximal gradient method, which is a combination of generalized forward-backward splitting and the Chambolle-Pock optimization algorithm, can be employed.

Instead of obtaining the tolerance statistic 92 from defect-free representations 94 only, the tolerance statistic 92 can comprise a joint probability density function f (S,R) or a conditional probability density function f (S|R) obtained by a density estimation technique, wherein S comprises observation representations 88 of subsets of observed imaging datasets 28 and/or defect-free representations 94 of subsets of defect-free observed imaging datasets 30, and wherein R comprises reference representations 104 of subsets of reference images 66, with respect to a number of characteristic elements 90. The corresponding probability distribution P (S,R) or P (S|R) respectively, models the joint or conditional distribution, thereby assigning a likelihood to pairs of subsets of reference images 66 and observed images 28. The observation representations 88 of subsets of observed imaging datasets 28 as well as the defect-free representations 94 of subsets of defect-free observed imaging datasets 30 can be obtained based on a number of additional characteristic elements 91, which can be derived from observed imaging datasets 28 and/or defect-free observed imaging datasets 30. For example, let x₁, . . . , xₖ denote subsets of reference images 66 and y1, . . . , ym subsets of observed imaging datasets 28 and/or defect-free observed imaging datasets 30, then the characteristic elements 90 C can be obtained by solving the following optimization problem

$$C = {argmin}_{C , {r}_{i} ∈ {ℝ}^{{n}_{1}}} {\sum }_{i = 1}^{k} {‖ C \cdot {r}_{i} - {x}_{i} ‖}_{2}^{2} + λ \cdot {\vert {r}_{i} \vert}_{1} , s . t . ‖ {C}_{i} ‖ = 1 ,$$

and the additional characteristic elements 91 A can be obtained by solving the following optimization problem

$$A = {argmin}_{C , {s}_{i} ∈ {ℝ}^{{n}_{2}}} {\sum }_{i = 1}^{m} {‖ A \cdot {s}_{i} - {y}_{i} ‖}_{2}^{2} + λ \cdot {\vert {s}_{i} \vert}_{1} , s . t . ‖ {A}_{i} ‖ = 1.$$

For a given pair comprising a subset of an observed imaging dataset 28 and/or a subset of a defect-free observed imaging dataset 30 x and a corresponding subset of a reference image 66 y, the reference representations 104 with respect to the characteristic elements 90 C and the observation representations 88 and/or the defect-free representations 94 with respect to the number of additional characteristic elements 91 A can be obtained by

$$\overline{r} = {argmin}_{r} \{ {\vert x - C \cdot r \vert}_{{L}_{p}} + {λ}_{1} {\vert r \vert}_{1} \} ,$$

$$\overline{s} = {argmin}_{s} \{ {\vert y - A \cdot s \vert}_{{L}_{p}} + {λ}_{2} {\vert s \vert}_{1} \} .$$

Defects 39 can then be detected based on the joint probability P (s, F) or based on the conditional probability P (s|7) and a characteristic property of the distribution, e.g., a threshold:

$$P ( \overline{s} \vert \overline{r} ) < τ or P ( \overline{s} , \overline{r} ) < τ .$$

Alternatively, the distribution can be used as a prior in an optimization problem comprising the reconstruction error of subsets x of imaging datasets 28, wherein the corresponding subset of a reference image 66 y has a reference representation r:

$$\overline{s} = {argmin}_{s} \{ {\vert x - A \cdot s \vert}_{{L}_{p}} + {λ}_{2} {\vert s \vert}_{1} - γ ln P ( \overline{s} , \overline{r} ) \}$$

Defects 39 can then be detected based on the reconstruction error |x−A·s̅|_{L}_{ₚ}, e.g., |x−A·s̅|_{L}_{ₚ}>τ for a threshold t.

A reference image 66 is a corresponding reference image 66 of an imaging dataset 28, 30 if it comprises the same or nearly the same semiconductor structures as the imaging dataset 28, 30. A subset of a reference image 66 is a corresponding subset of a reference image 66 of a subset of an imaging dataset 28, 30 if it comprises the same or nearly the same semiconductor structures as the subset of the imaging dataset 28, 30.

According to an aspect of the example, the characteristic elements 90 comprise independent components obtained via independent component analysis. The characteristic elements 90 can also comprise a number of image-patches obtained by an unsupervised clustering method, e.g., by k-means, agglomerative clustering or perception-driven clustering, etc.

In an example of the first or second embodiment of the disclosure, the reference images 66 of semiconductor structures comprise subsets of defect-free observed imaging datasets 30 of semiconductor structures. The reference images 66 of semiconductor structures can also comprise subsets of defect-free generated images of semiconductor structures, for example including synthetic images of defect-free semiconductor structures. The defect-free generated images of semiconductor structures can comprise a number of polygons representing semiconductor structures, e.g., as illustrated in FIGS. 3A and 5A. The defect-free generated images of semiconductor structures can comprise images generated from a defect-free CAD model of a wafer. In this case, a mask can be applied to the CAD model to ignore irrelevant sections of the CAD model, e.g., irrelevant sections, defective sections or sections containing insufficient information.

The generated images can be emulated to have an appearance similar to an observed imaging dataset 28 of the wafer 24 by simulating the image acquisition process and the photolithography process 10. The emulated images can be computed via a machine learning model. The reference images 66 can comprise defect-free generated images of semiconductor structures and defect-free observed images of the semiconductor structures.

In an example of the first or second embodiment of the disclosure, the observation representation 88 of a subset of an observed imaging dataset 28 comprises spatial information regarding the location of the subset within the imaging dataset 28 and/or the defect-free representation 94 of a subset of a defect-free observed imaging dataset 30 comprises spatial information regarding the location of the subset within the defect-free observed imaging dataset 30 and/or the reference representation 104 of a subset of a reference image 66 comprises spatial information regarding the location of the subset within the reference image 66. For example, the pixel location can be encoded in this way. To this end, the spatial information can comprise positional encodings, in particular Fourier functions of different frequencies.

Positional encodings, also known as “Fourier Features”, is a popular technique for encoding spatial coordinates by generating positional features as a set of sine and cosine waves with different frequencies. For example, the feature for a 1-D position x could be represented by the following vector

$${( sin ( x \cdot π ) , cos ( x \cdot μ ) , sin ( x \cdot μ / 2 ) , cos ( x \cdot μ / 2 ) , sin ( x \cdot μ / 4 ) , cos ( x \cdot μ / 4 ) , … )}^{T}$$

The positional encodings vector can comprise the same number of dimensions as the representation vector. Both vectors can be concatenated to form a single representation. For example, the tolerance statistic 92 can be learned from these defect-free representations 94 comprising spatial information.

In an example of the first or second embodiment of the disclosure, a subset comprises a single pixel. A subset of an imaging dataset 28 can also comprise a section of an observed imaging dataset 28. A subset of a defect-free observed imaging dataset 30 can also comprise a section of the defect-free observed imaging dataset 30. A subset of a reference image 66 can comprise a section of the reference image 66. The observation representation 88 of a subset of an imaging dataset 28 can be obtained from a region of interest comprising the subset of the imaging dataset 28. The defect-free representation 94 of a subset of a defect-free observed imaging dataset 30 can be obtained from a region of interest comprising the subset of the defect-free observed imaging dataset 30. The reference representation 104 of a subset of a reference image 66 can be obtained from a region of interest comprising the subset of the reference image 66.

The detected defects 39 can be classified according to the type of defect 39. In an example of the first or second embodiment of the disclosure, therefore, a machine learning model is trained to assign a defect type from a predefined set of defect types to an observation representation 88 of a subset of an imaging dataset 28 of a wafer 24, the observation representation 88 being based on the number of characteristic elements 90. The machine learning model can be trained on training data associating defect types such as the ones referred to in FIG. 3D with defects 39. Additionally or alternatively, the defects can be labeled with their defect type by a human. Additionally or alternatively, defects can be labeled by a rule based algorithm, which applies predefined rules to a given defect 39 to infer the type of defect 39. Based on the type of defect 39, the defect 39 can be directly addressed to the respective hardware or system part, e.g. bridge defects 42 or line thinning defects 40 to the etching unit, missing structure defects to the illumination unit etc.

According to an aspect of an example of the first or second embodiment of the disclosure, information about the computer implemented methods can be stored, e.g., characteristic elements 90, the tolerance statistic 92, reference images 66, defect-free observed imaging datasets 30 or any other parameter of the defect detection method for future use-cases or for analysis of the defect criterion or the learning process. Intermediate results, e.g. characteristic elements, difference images or reconstruction errors can also be provided as input data to other methods. Fixed inputs such as reference images 66, characteristic elements 90 or the tolerance statistic 92 can be provided by an exchangeable hardware.

In any example of the first or second embodiment of the disclosure, the imaging dataset of the wafer can be obtained via a charged particle beam system. A charged particle beam system includes, but is not limited to, a scanning electron microscope (SEM), a focused ion beam microscope, such as Helium ion microscope. A further example of charged particle beam system is a corrected electron scanning microscope, comprising a correction mechanism for correction of chromatic aberration and spherical aberration.

In order to present input data, intermediate or final results to a user, a visualization mechanism can be used. According to an example of the first or second embodiment of the disclosure, an observation representation 88 of a subset of an imaging dataset 28 of a wafer 24 and/or characteristic elements 90 and/or detected defects 39 in an imaging dataset 28 of a wafer 24 are directed to a display device 136 or dashboard for visualization. Characteristic elements 90 such as dictionaries comprising a number of atoms can, for example, be visualized by heatmaps. The same holds true for defect probabilities. To obtain an overview of the results, can be desirable to visualize the inspected subset of the imaging dataset 28 of the wafer 24 together with the characteristic elements 90, the observation representation 88 of the subset and the detected defects 39. In this way, real-time monitoring of the detected defects 39 is possible. Alternatively, the data can be stored in a long-term memory for further analysis, e.g., for generating statistics over defects 39. In a further example, the recognized defects 39 can be cached into a memory for a specified timespan, e.g., for 48 hours to allow for a further analysis of the detected defects 39 but without requiring a lot of memory.

An example of the first or second embodiment of the disclosure further comprises directing detected defects 39 in an imaging dataset 28 of a wafer 24 to a display device 136 or dashboard for visualization, wherein the detected defects 39 are highlighted or labeled according to the type of defect 39. For example, a specific type of defect 39 such as bridge defects 42 can be marked in a specific color or labeled with a corresponding text.

For quality assurance or quality control processes, it is desirable to obtain further information about the detected defects. Therefore, an example of a first or second embodiment of the disclosure can further comprise determining one or more measurements of the recognized defects 39 in a subset of the imaging dataset 28 of the wafer 24, in particular size, area, dimension, shape parameters, distance, radius, aspect ratio, type, number of defects, density, spatial distribution of defects, existence of any defects, etc. Such measurements can be obtained only for specific types of defects or only within a specific region of the imaging dataset 28, e.g. a border or die region or a user-defined region, which can be marked by a mask.

For quality control, an example of the first or second embodiment of the disclosure can further comprise assessing the quality of the wafer 24 based on the one or more measurements and at least one quality assessment rule, e.g., according to a DIN-ISO quality specification, which defines the upper limits for acceptability of non-ideal wafers. For example, the density of a specific defect type at die-cores should be lower than 10 per nm².

According to any one of the embodiments of the disclosure, at least one wafer manufacturing process parameter can be controlled based on the one or more measurements of the recognized defects in the imaging dataset of the wafer.

The disclosure also relates to a computer-readable medium, having stored thereon a computer program executable by a computing device, the computer program comprising code for executing a method according to any of the embodiments of the disclosure.

The disclosure also relates to a computer program product comprising instructions which, when the program is executed by a computer, cause the computer to carry out a method according to any of the embodiments of the disclosure.

FIG. 12 schematically illustrates a system 122, which can be used for controlling the quality of wafers 24 produced in a semiconductor manufacturing fab. The system 122 includes an imaging device 124 and a processing device 126. The imaging device 124 is coupled to the processing device 126. The imaging device 124 is configured to acquire imaging datasets 28 of the wafer 24. The wafer 24 can include semiconductor structures, e.g., transistors such as field effect transistors, memory cells, et cetera. An example implementation of the imaging device 124 would be a SEM or multibeam SEM, a Helium ion microscope (HIM) or a cross-beam device including FIB and SEM or any charged particle imaging device.

The imaging device 124 can provide an imaging dataset 28 to the processing device 126. The processing device 126 includes a processor, e.g., implemented as a CPU 128 or GPU. The processor can receive the imaging dataset 28 via an interface 130. The processor can load program code from a memory 132. The processor can execute the program code. Upon executing the program code, the processor performs techniques such as described herein according to a first or second embodiment of the disclosure, e.g., defect detection, taking measurements of detected defects, computing an observation representation 88 of a subset of an imaging dataset 28 with respect to a number of characteristic elements 90, computing a tolerance statistic 92 from defect-free representations 94 of defect-free observed imaging datasets 30, computing characteristic elements 90 from reference images 66. For example, the processor can perform the computer implemented method shown in FIG. 7 or 8 upon loading program code from the memory 132. The processing device 126 can optionally contain a user interface 134 for receiving user input, e.g., defect measurement types, quality assessment rules, parameters for machine learning models, emulation parameters, parameters for aligning imaging datasets 28 and reference images 66 etc. The processing device 126 can optionally contain a display device 136 for displaying defect detection results, input data or intermediate results to a user, e.g. in real-time or buffered.

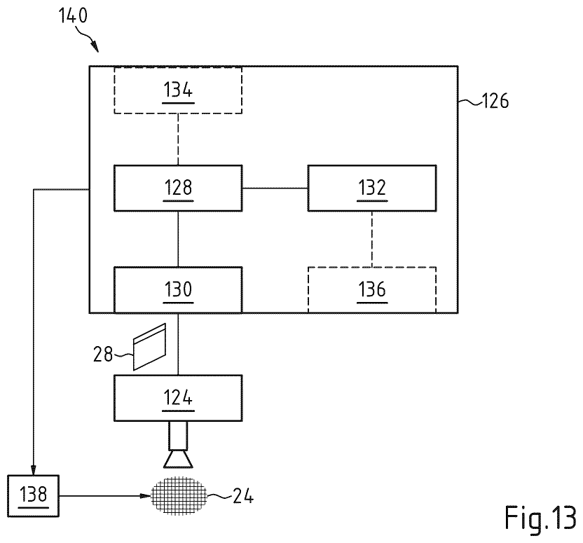

FIG. 13 schematically illustrates a system 140, which can be used for controlling the production of wafers 24 in a semiconductor manufacturing fab. The system 122 comprises the same components as indicated in FIG. 12 and the above the also applies for the respective components here. In addition, the system 122 has a mechanism 138 for producing wafers 24 controlled by at least one wafer manufacturing process parameter. To this end, an imaging dataset 28 is provided to the processing device 126 via the imaging device 124. The processor of the processing device 126 is configured to perform one of the disclosed methods comprising controlling the at least one wafer manufacturing process parameter based on one or more measured properties of the recognized defects 39 in the imaging dataset 28 of the wafer 24. For example, detected bridge defects 42 indicate insufficient etching, so the amount of etching is increased, detected line break defects 48 indicate excessive etching, so the amount of etching is decreased, consistently occurring anomalies or defects 39 indicate a defective mask 16, so the mask 16 is to be checked, and defects 39 due to missing structures hint at non-ideal material deposition, so the material deposition is modified.

Embodiments, examples and aspects of the disclosure can be described by the following clauses

1. Computer implemented method 82 for defect detection comprising:
Obtaining an imaging dataset 28 of a wafer 24 comprising semiconductor structures;
Verifying a defect criterion for defect detection in a subset of the imaging dataset 28 of the wafer 24, the defect criterion comprising
   i. an observation representation 88 of the subset of the imaging dataset 28 with respect to a number of characteristic elements 90 derived from reference images 66 of semiconductor structures, wherein the observation representation and the characteristic elements 90 define a reconstruction of minimal reconstruction error of the subset of the imaging dataset 28, and
   ii. a tolerance statistic 92 on defect-free representations 94 of subsets of defect-free observed imaging datasets 30 of wafers 24, wherein each of the defect-free representations and the characteristic elements 90 define a reconstruction of minimal reconstruction error of a subset of the defect-free imaging datasets 30;
Generating defect information for the subset of the imaging dataset 28 based on the defect criterion.

2. Method according to clause 1, wherein the observation representation 88 of the subset of an imaging dataset 28 comprises coefficients of a decomposition 120 of the subset of the imaging dataset 28 with respect to the number of characteristic elements 90, and wherein the defect-free representations 94 of the subsets of the defect-free observed imaging datasets 30 comprise coefficients of decompositions 120 of the subsets of the defect-free observed imaging datasets 30 with respect to the number of characteristic elements 90.

3. Method according to clause 2, wherein the decomposition 120 is a linear decomposition 120.

4. Method according to clause 2 or 3, wherein the characteristic elements 90 comprise elements of a basis.

5. Method according to clause 4, wherein the characteristic elements 90 comprise elements of a wavelet basis.

6. Method according to clause 4 or 5, wherein the characteristic elements 90 comprise elements of a Fourier basis.

7. Method according to any one of clauses 4 to 6, wherein the characteristic elements 90 comprise a number of principal components obtained via principal component analysis.

8. Method according to any one of clauses 2 to 7, wherein the characteristic elements 90 comprise elements of an overcomplete frame.

9. Method according to any one of clauses 2 to 8, wherein the characteristic elements 90 comprise elements of a dictionary 121 obtained via dictionary learning.

10. Method according to any one of clauses 2 to 9, wherein the characteristic elements 90 comprise a number of independent components obtained via independent component analysis.

11. Method according to any one of clauses 2 to 10, wherein the characteristic elements 90 comprise a number of image-patches obtained by an unsupervised clustering method.

12. Method according to clause 1, wherein the observation representation 88 of the subset of the imaging dataset 28 comprises a registration vector indicating the offset between the subset of the imaging dataset 28 and a characteristic element 90 in the form of a corresponding subset of a reference image 66, such that the corresponding subset of the reference image 66 is registered with the subset of the imaging dataset 28 via the registration vector, and wherein the defect-free representations 94 of the subsets of the defect-free observed imaging datasets 30 comprise registration vectors indicating the offset between the subsets of the defect-free observed imaging datasets 30 and characteristic elements 90 in the form of corresponding subsets of reference images 66, such that the corresponding subsets of the reference images 66 are registered with the subsets of the defect-free observed imaging datasets 30 via the registration vectors.

13. Method according to clause 12, wherein the reconstruction error of a subset of an imaging dataset 28 comprises the warping error between the subset of the imaging dataset 28 and the corresponding subset of the reference image 66, and wherein the reconstruction error of a defect-free representation 94 of a subset of a defect-free observed imaging dataset 30 comprises the warping error between the subset of the defect-free observed imaging dataset 30 and the corresponding subset of the reference image 66.

14. Method according to clause 1, wherein the number of characteristic elements 90 comprises a machine learning model trained on the reference images 66 of semiconductor structures, and wherein the observation representation 88 of the subset of the imaging dataset 28 comprises the output of the machine learning model when applied to the subset of the imaging dataset 28, and wherein the defect-free representations 94 of the subsets of the defect-free observed imaging datasets 30 comprise the output of the machine learning model when applied to the subsets of the defect-free observed imaging datasets 30.

15. Method according to clause 14, wherein the machine learning model comprises a neural network 118.

16. Method according to any one of the preceding clauses, wherein the defect criterion comprises detecting a defect 39 in the subset of the imaging dataset 28 based on a statistical property of the obtained observation representation 88 with respect to the tolerance statistic 92.

17. Method according to clause 16, wherein the statistical property comprises a quantile of the tolerance statistic 92, in particular a threshold.

18. Method according to clause 16 or 17, wherein the statistical property comprises a confidence interval.

19. Method according to any one of clauses 16 to 18, wherein the statistical property comprises a moment of the tolerance statistic 92, in particular a mean value and/or a variance.

20. Method according to any one of the preceding clauses, wherein the observation representation 88 of the subset of the imaging dataset 28 is obtained by solving an optimization problem comprising the reconstruction error and a prior comprising the tolerance statistic 92 on defect-free representations 94.

21. Method according to clause 20, wherein the defect criterion comprises detecting a defect 39 in the subset of the obtained imaging dataset 28 based on the reconstruction error of the solution to the optimization problem.

22. Method according to any one of the preceding clauses, wherein the tolerance statistic 92 comprises a probability density function obtained from the defect-free representations 94 of defect-free observed imaging datasets 30 by a density estimation technique.

23. Method according to clause 22, wherein the probability density function of the tolerance statistic 92 is obtained by a parametric density estimation technique, in particular the probability density function of a Gaussian or a Gaussian mixture model.

24. Method according to clause 22, wherein the probability density function of the tolerance statistic 92 is obtained by a non-parametric density estimation technique, in particular a Parzen density estimator.

25. Method according to any one of the preceding clauses, wherein the tolerance statistic 92 comprises a machine learning model trained on the defect-free representations 94 of the subsets of the defect-free observed imaging datasets 30, in particular a one-class SVM or a support vector data description.

26. Method according to any one of the preceding clauses, wherein the tolerance statistic 92 comprises only a subset of the dimensions of the defect-free representations 94 of the subsets of the defect-free observed imaging datasets 30.

27. Method according to any one of the preceding clauses, wherein the tolerance statistic 92 comprises a separate tolerance statistic for each dimension of the subset of dimensions of the defect-free representations 94 of the subsets of the defect-free observed imaging datasets 30.

28. Method according to any one of the preceding clauses, wherein the reference images 66 of semiconductor structures comprise subsets of defect-free observed imaging datasets 30 of semiconductor structures.

29. Method according to any one of the preceding clauses, wherein the reference images 66 of semiconductor structures comprise subsets of defect-free generated images of semiconductor structures.

30. Method according to clause 29, wherein the defect-free generated images of semiconductor structures comprise synthetic images of defect-free semiconductor structures.

31. Method according to clause 29 or 30, wherein the defect-free generated images of semiconductor structures comprise a number of polygons representing semiconductor structures.

32. Method according to any one of clauses 29 to 31, wherein the defect-free generated images of semiconductor structures comprise images generated from a defect-free CAD model of a wafer.

33. Method according to any one of clauses 29 to 32, wherein the generated images are emulated to have an appearance similar to an observed imaging dataset 28 of the wafer 24 by simulating the image acquisition process and the lithography process.

34. Method according to any one of the preceding clauses, wherein the reference images 66 comprise defect-free generated images of semiconductor structures and defect-free observed images of the semiconductor structures.

35. Method according to any one of the preceding clauses, wherein the reference images 66 are aligned.

36. Method according to any one of the preceding clauses, wherein the observation representation 88 of the subset of the observed imaging dataset 28 comprises spatial information regarding the location of the subset within the imaging dataset 28, and wherein the defect-free representations 94 of the subsets of the defect-free observed imaging datasets 30 comprise spatial information regarding the location of the subsets within the defect-free observed imaging datasets 30.

37. Method according to clause 36, wherein the spatial information comprises positional encodings comprising Fourier functions of different frequencies.

38. Method according to any one of the preceding clauses, wherein the subset comprises a single pixel.

39. Method according to any one of the preceding clauses, wherein the observation representation 88 of the subset of the imaging dataset 28 is obtained from a region of interest comprising the subset of the imaging dataset 28, and wherein the defect-free representations 94 of the subsets of the defect-free observed imaging datasets 30 are obtained from regions of interest comprising the subsets of the defect-free observed imaging datasets 30.

40. Method according to any one of the preceding clauses, the defect criterion further comprising modifying the defect detection result via a trained machine learning model 95.

41. Method according to any one of the preceding clauses, further comprising modifying an intermediate result of the computer implemented method for defect detection 82 via a trained machine learning model 95.

42. Method according to clause 41, wherein the trained machine learning model 95 is applied to the subset of the imaging dataset 28 and/or to a difference of the subset of the imaging dataset 28 and an aligned reference image 66, in particular an emulated aligned reference image 67, and/or to the reconstruction error of the observation representation 88 of the subset of the imaging dataset 28.

43. Method according to any one of clauses 40 to 42, wherein the trained machine learning model 95 comprises an autoencoder.

44. Method according to any one of clauses 40 to 43, wherein the trained machine learning model 95 comprises a segmentation model.

45. Method according to any one of the preceding clauses, wherein a machine learning model is trained to assign a defect type from a predefined set of defect types to a subset of an imaging dataset 28 of a wafer 24 and the defect 39 is communicated to a specific hardware unit responsible for the defect.

46. Method according to any one of the preceding clauses, wherein the imaging dataset 28 is obtained via a charged particle beam system, in particular by multibeam scanning electron microscopy.

47. Method according to any one of the preceding clauses, further comprising directing an observation representation 88 of a subset of an imaging dataset 28 of a wafer 24 and/or characteristic elements 90 and/or detected defects 39 in an imaging dataset 28 of a wafer 24 to a display device 136 or dashboard for visualization.

48. Method according to any one of the preceding clauses, further comprising directing detected defects 39 in an imaging dataset 28 of a wafer 24 to a display device 136 or dashboard for visualization, wherein the detected defects 39 are highlighted or labeled according to the type of defect.

49. Method according to any one of the preceding clauses, wherein reference images 66, characteristic elements 90 and/or the tolerance statistic 92 is provided via an exchangeable hardware.

50. Computer implemented method 96 for obtaining a tolerance statistic 92 on defect-free representations 94 of subsets of defect-free observed imaging datasets 30 of wafers 24, comprising the following steps:
i. Obtaining defect-free observed imaging datasets 30 of wafers 24 comprising semiconductor structures;
ii. Generating defect-free representations 94 of subsets of defect-free observed imaging datasets 30 of wafers 24 with respect to a number of characteristic elements 90 derived from reference images 66 of semiconductor structures, wherein each of the defect-free representations 94 and the characteristic elements 90 define a reconstruction of minimal reconstruction error of a subset of the defect-free observed imaging datasets 30; and iii. Obtaining a tolerance statistic 92 on the defect-free representations 94.

51. Method according to clause 50, further comprising, before step ii., obtaining a number of characteristic elements 90 from reference images 66 of semiconductor structures by solving an optimization problem comprising a minimal reconstruction error of reconstructions of reference images 66, the reconstructions being defined by reference representations 104 and the characteristic elements 90.

52. Method according to clause 51, wherein the optimization problem comprises at least one constraint or prior on a characteristic element 90.

53. Method according to clause 52, wherein the constraint or prior involves the sparsity of the characteristic element 90, in particular the L0-norm or the L1-norm or the kurtosis of the characteristic element 90.

54. Method according to any one of clauses 51 to 53, wherein the optimization problem comprises at least one constraint or prior on a reference representation 104.

55. Method according to clause 54, wherein the constraint or prior is a measure of sparsity of the reference representation 104, in particular the L0-norm or the L1-norm or the kurtosis of the reference representation 104.

56. Method according to any one of the preceding clauses, further comprising determining one or more measurements of the recognized defects 39 in a subset of the imaging dataset 28, in particular size, area, dimension, shape parameters, distance, radius, aspect ratio, type, number of defects, density, spatial distribution of defects, existence of defects, etc.

57. Method according to clause 56, further comprising assessing the quality of the wafer based on the one or more measurements and at least one quality assessment rule.

58. Method according to clause 56, further comprising controlling at least one wafer manufacturing process parameter based on one or more measurements of the recognized defects in the imaging dataset 28.

59. Computer-readable medium, having stored thereon a computer program executable by a computing device, the computer program comprising code for executing a method of any one of clauses 1 to 58.

60. Computer program product comprising instructions which, when the program is executed by a computer, cause the computer to carry out a method of any one of clauses 1 to 58.

61. System 122 for controlling the quality of wafers 24 produced in a semiconductor manufacturing fab, the system 122 comprising:
an imaging device 124 adapted to provide an imaging dataset 28 of a wafer 24;
one or more processing devices 126;
one or more machine-readable hardware storage devices comprising instructions that are executable by one or more processing devices 126 to perform operations comprising the method of clause 57.

62. System 140 for controlling the production of wafers 24 in a semiconductor manufacturing fab, the system 140 comprising:
means 138 for producing wafers 24 controlled by at least one manufacturing process parameter;
an imaging device 124 adapted to provide an imaging dataset 28 of a wafer 24;
one or more processing devices 126;
one or more machine-readable hardware storage devices comprising instructions that are executable by one or more processing devices 126 to perform operations comprising the method of clause 58.

63. System 122, 140 according to clause 61 or 62, further comprising a display device 136.

10 64. System 122, 140 according to any one of clauses 61 to 63, further comprising a user interface 134.

### REFERENCE NUMBER LIST

10 Photolithography process
12 Substrate
14 Photoresist
15 Radiation
16 Mask
18 Etching
20 Washing
22 Inspection process
24 Wafer
26 Microscope
28 Imaging dataset
30 Defect-free observed imaging dataset
32 Error-prone imaging dataset
34 Nuisance
36 Line shortening
37 Line thinning
38 Edge roughness
39 Defect
40 Line thinning defect
42 Bridge defect
44 Long bridge defect
46 Intrusion defect
48 Line break defect
50 Excursion defect
52 Line pullback defect
54 Spurious structure defect
56 Die-to-database workflow
58 Rasterization step
60 Anchor point step
62 Alignment step
64 Emulation step
66 Reference image
67 Aligned emulated reference image
68 Differencing step
70 Post-processing step
72 Defect proposals
74 Marking
76 Local context
78 Marking
80 Local context
82 Computer implemented method
84 Imaging step
86 Defect criterion verification step
88 Observation representation
90 Characteristic elements
91 Additional characteristic elements
92 Tolerance statistic
94 Defect-free representation
95 Machine learning model
96 Computer implemented method
98 Imaging step
99 Characteristic element step
100 Representation generation step
102 Tolerance statistic step
104 Reference representation
106 Emulated reference image
108 Registration step
112 Zero offset registration vectors
114 Non-zero offset registration vectors
116 Optional
118 Neural network
120 Decomposition
122 System
124 Imaging device
126 Processing device
128 CPU
130 Interface
132 Memory
134 User interface
136 Display device
138 Mechanism

What is claimed is:

1. A computer implemented method, comprising:
obtaining an imaging dataset of a wafer comprising semiconductor structures;
verifying a defect criterion for defect detection in a subset of the imaging dataset of the wafer, the defect criterion comprising:
an observation representation of the subset of the imaging dataset with respect to a number of characteristic elements derived from reference images of semiconductor structures, the observation representation and the characteristic elements defining a reconstruction of minimal reconstruction error of the subset of the imaging dataset; and
a tolerance statistic on defect-free representations of subsets of defect-free observed imaging datasets of wafers, each of the defect-free representations and the characteristic elements defining reconstruction of minimal reconstruction error of a subset of the defect-free imaging datasets; and
generating defect information for the subset of the imaging dataset based on the defect criterion.

2. The method of claim 1, wherein the observation representation of the subset of an imaging dataset comprises coefficients of a decomposition of the subset of the imaging dataset with respect to the number of characteristic elements, and the defect-free representations of the subsets of the defect-free observed imaging datasets comprise coefficients of decompositions of the subsets of the defect-free observed imaging datasets with respect to the number of characteristic elements.

3. The method of claim 2, wherein the decomposition is a linear decomposition.

4. The method of claim 2, wherein the characteristic elements comprise at least one of the following:
elements of a basis;
elements of a wavelet basis
elements of a Fourier basis
a number of principal components obtained via principal component analysis;
elements of an overcomplete frame;
elements of a dictionary obtained via dictionary learning;
a number of independent components obtained via independent component analysis; and
a number of image-patches obtained by an unsupervised clustering method.

5. The method of claim 1, wherein:
the observation representation of the subset of the imaging dataset comprises a registration vector indicating the offset between the subset of the imaging dataset and a characteristic element in the form of a corresponding subset of a reference image so that the corresponding subset of the reference image is registered with the subset of the imaging dataset via the registration vector; and
the defect-free representations of the subsets of the defect-free observed imaging datasets comprise registration vectors indicating the offset between the subsets of the defect-free observed imaging datasets and characteristic elements in the form of corresponding subsets of reference images so that the corresponding subsets of the reference images are registered with the subsets of the defect-free observed imaging datasets via the registration vectors.

6. The method of claim 5, wherein:
the reconstruction error of a subset of an imaging dataset comprises a warping error between the subset of the imaging dataset and the corresponding subset of the reference image; and
the reconstruction error of a defect-free representation of a subset of a defect-free observed imaging dataset comprises a warping error between the subset of the defect-free observed imaging dataset and the corresponding subset of the reference image.

7. The method of claim 1, wherein:
the number of characteristic elements comprises a machine learning model trained on the reference images of semiconductor structures;
the observation representation of the subset of the imaging dataset comprises the output of the machine learning model when applied to the subset of the imaging dataset; and
the defect-free representations of the subsets of the defect-free observed imaging datasets comprise the output of the machine learning model when applied to the subsets of the defect-free observed imaging datasets.

8. The method of claim 7, wherein the machine learning model comprises a neural network.

9. The method of claim 1, wherein the defect criterion comprises detecting a defect in the subset of the imaging dataset based on a statistical property of the obtained observation representation with respect to the tolerance statistic.

10. The method of claim 9, wherein the statistical property comprises at least one of the following:
a quantile of the tolerance statistic;
a threshold of the tolerance statistic;
a confidence interval;
a moment of the tolerance statistic;
a mean value of the tolerance statistic; and
a variance of the tolerance statistic.

11. The method of claim 1, wherein the observation representation of the subset of the imaging dataset is obtained by solving an optimization problem comprising the reconstruction error and a prior comprising the tolerance statistic on defect-free representations.

12. The method of claim 11, wherein the defect criterion comprises detecting a defect in the subset of the obtained imaging dataset based on the reconstruction error of the solution to the optimization problem.

13. The method of claim 1, wherein the tolerance statistic comprises a probability density function obtained from the defect-free representations of defect-free observed imaging datasets by a density estimation technique.

14. The method of claim 13, wherein at least one of the following holds:
the probability density function of the tolerance statistic is obtained by a parametric density estimation technique;
the probability density function of the tolerance statistic is obtained by a probability density function of a Gaussian or a Gaussian mixture model;
the probability density function of the tolerance statistic is obtained by a non-parametric density estimation technique; and
the probability density function of the tolerance statistic is obtained by a Parzen density estimator.

15. The method of claim 1, wherein the tolerance statistic comprises a machine learning model trained on the defect-free representations of the subsets of the defect-free observed imaging datasets.

16. The method of claim 1, wherein at least one of the following holds:
the tolerance statistic comprises only a subset of the dimensions of the defect-free representations of the subsets of the defect-free observed imaging datasets;
the tolerance statistic comprises a separate tolerance statistic for each dimension of the subset of dimensions of the defect-free representations of the subsets of the defect-free observed imaging datasets;
the reference images of semiconductor structures comprise subsets of defect-free observed imaging datasets of semiconductor structures; and
the reference images of semiconductor structures comprise subsets of defect-free generated images of semiconductor structures.

17. The method of claim 1, wherein:
the reference images of semiconductor structures comprise subsets of defect-free generated images of semiconductor structures; and at least one of the following holds:
the defect-free generated images of semiconductor structures comprise synthetic images of defect-free semiconductor structures;
the defect-free generated images of semiconductor structures comprise a number of polygons representing semiconductor structures;
the defect-free generated images of semiconductor structures comprise images generated from a defect-free CAD model of a wafer; and
the generated images are emulated to have an appearance similar to an observed imaging dataset of the wafer by simulating the image acquisition process and the lithography process.

18. The method of claim 1, wherein at least one of the following holds:
the reference images comprise defect-free generated images of semiconductor structures and defect-free observed images of the semiconductor structures;
the reference images are aligned;
the observation representation of the subset of the observed imaging dataset comprises spatial information regarding the location of the subset within the imaging dataset, and the defect-free representations of the subsets of the defect-free observed imaging datasets comprise spatial information regarding the location of the subsets within the defect-free observed imaging datasets;
the spatial information comprises positional encodings comprising Fourier functions of different frequencies;
the subset comprises a single pixel;
the observation representation of the subset of the imaging dataset is obtained from a region of interest comprising the subset of the imaging dataset, and the defect-free representations of the subsets of the defect-free observed imaging datasets are obtained from regions of interest comprising the subsets of the defect-free observed imaging datasets;
the defect criterion further comprising modifying the defect detection result via a trained machine learning model; and
the method further comprises modifying an intermediate result of the computer implemented method for defect detection via a trained machine learning model.

19. The method of claim 1, wherein at least one of the following holds:
a machine learning model is trained to assign a defect type from a predefined set of defect types to a subset of an imaging dataset of a wafer and the defect is communicated to a specific hardware unit responsible for the defect;
the imaging dataset is obtained via a charged particle beam system;
the method further comprises directing an observation representation of a subset of an imaging dataset of a wafer and/or characteristic elements and/or detected defects in an imaging dataset of a wafer to a display device or dashboard for visualization;
the method further comprises directing detected defects in an imaging dataset of a wafer to a display device or dashboard for visualization, and the detected defects are highlighted or labeled according to the type of defect;
reference images, characteristic elements and/or the tolerance statistic is provided via an exchangeable hardware.

20. One or more machine-readable hardware storage devices comprising instructions that are executable by one or more processing devices to perform operations comprising the method of claim 1.

21. A system, comprising:
one or more processing devices; and
one or more machine-readable hardware storage devices comprising instructions that are executable by one or more processing devices to perform operations comprising the method of claim 1.

22. A computer implemented method, comprising:
obtaining defect-free observed imaging datasets of wafers comprising semiconductor structures;
generating defect-free representations of subsets of defect-free observed imaging datasets of wafers with respect to a number of characteristic elements derived from reference images of semiconductor structures, each of the defect-free representations and the characteristic elements defining a reconstruction of minimal reconstruction error of a subset of the defect-free observed imaging datasets; and
obtaining a tolerance statistic on the defect-free representations.

23. One or more machine-readable hardware storage devices comprising instructions that are executable by one or more processing devices to perform operations comprising the method of claim 1.

24. A system, comprising:
one or more processing devices; and
one or more machine-readable hardware storage devices comprising instructions that are executable by one or more processing devices to perform operations comprising the method of claim 1.
